(19) United States
(12) Patent Application Publication
(10) Pub. No.: US 2021/0159728 A1
(43) Pub. Date: May 27, 2021

(54) SYSTEMS AND METHODS FOR INTEGRITY CHECKS FOR SAFETY FEATURES IN A POWER DISTRIBUTION NETWORK

(71) Applicant: Corning Research & Development Corporation, Corning, NY (US)

(72) Inventor: Alexey Mestezky, Holon (IL)

(21) Appl. No.: 17/097,354

(22) Filed: Nov. 13, 2020

Related U.S. Application Data
(60) Provisional application No. 62/939,839, filed on Nov. 25, 2019.

(51) Int. Cl. H02J 13/00

(52) U.S. Cl. CPC H02J 13/00016; G01R 31/52; H02J 13/0004

(57) ABSTRACT

Safety power disconnection integrity check for power distribution over power conductors to radio communications circuits monitors the integrity of circuit breakers may be used in an operating protection circuit as well as the integrity of current sensors in the operating protection circuit. Such monitoring includes testing the ability of individual switches to disconnect, testing the correctness of a leakage current sensor reading, and testing a correctness of an over current sensor reading. To perform these tests, the individual element is isolated and provided a test current. Any alarms generated by the element under test are diverted so that operation continues normally. Testing the safety power elements ensures that faults in the systems are detected and corrected so as to improve overall safety. Further, manual testing, which may interrupt service, is avoided.

### PRIORITY APPLICATION

The present application claims priority to U.S. Provisional Patent Application No. 62/939,839, filed on Nov. 25, 2019, and entitled “SAFETY POWER DISCONNECTION INTEGRITY CHECK FOR POWER DISTRIBUTION OVER POWER CONDUCTORS TO RADIO COMMUNICATIONS CIRCUITS,” the contents of which is incorporated herein by reference in its entirety.

### BACKGROUND

The disclosure relates generally to a power distribution network having safety features and, more particularly, to checking the integrity of such safety features. While a variety of environments are amenable to this integrity check, the power distribution network may be positioned in a distributed radio communication system (DCS) such as a distributed antenna systems (DAS) or a small cell radio access network for example.

The seemingly ubiquitous nature of power outlets leads many individuals to take the availability of electrical power for granted. Homes and offices routinely have an outlet on multiple, if not all, walls. Likewise, overhead lighting is readily powered such that a simple flick of a switch turns on such overhead lighting. However, as anyone who has wired a building for power will tell you, there are many factors which must be considered when routing electrical conductors to carry power to outlets and overhead lighting.

While conventional power outlets are seemingly ubiquitous, there are many situations where it is inconvenient or inappropriate to use such power outlets to provide power to some device. As noted above, lighting may have power supplied directly thereto without having to use an intermediate outlet. Similarly, high-power devices may be hard wired to have power supplied directly. Distributed communication systems are one such situation and may require a power distribution network or power distribution network that has a centralized power source and one or more subunits that receive power from the centralized power source. The problems of distributing power to radio communication circuits are not limited to communication systems. Lighting systems, smart homes with powered elements, Ethernet switches, water heating systems, server farms, call centers, or the like may all have distributed power systems.

Some regulations, such as International Electric Code (IEC) 60950-21, may limit the amount of direct current (DC) that is remotely delivered by the power source to the remote subunits to less than the amount needed to power the subunits during peak power consumption periods for safety reasons, such as in the event a human contacts the wire. One solution to remote power distribution limitations is to employ multiple conductors and split current from the power source over the multiple conductors, such that the current on any one electrical conductor is below the regulated limit. Another solution includes delivering remote power at a higher voltage so that a lower current can be distributed at the same power level. For example, assume that 300 Watts (W) of power is to be supplied to a subunit by the power source. If the voltage of the power source is 60 Volts (V), the current will be 5 Amperes (A) (i.e., 300 W/60 V). However, if a 400 V power source is used, then the current flowing through the wires will be 0.75 A. Delivering high voltage through electrical conductors may be further regulated to prevent an undesired current from flowing through a human in the event that a human contacts the electrical conductor. Likewise, there may be a need to prevent the line current from exceeding maximum allowed current values. Such regulations necessitate a variety of safety features and protection circuits. Once installed, the safety measures and protection circuits may fail and detection of such may be helpful.

No admission is made that any reference cited herein constitutes prior art. Applicant expressly reserves the right to challenge the accuracy and pertinence of any cited documents.

### SUMMARY

Exemplary aspects of systems and methods for integrity checks for safety features in a power distribution network are disclosed. In particular, the integrity of circuit breakers used in an operating protection system as well as the integrity of current sensors may be checked. In a specific exemplary aspect, such a check may include testing the ability of individual switches to disconnect, testing the correctness of a leakage current sensor reading, and testing the correctness of an over current sensor reading. To perform these tests, an individual element is isolated and provided a test current. Any alarms generated by the element under test are diverted or suppressed so that operation (i.e., power distribution) continues normally. The safety features remain intact during testing by virtue of the redundant circuits not being tested simultaneously. Testing the safety power elements ensures that faults in the systems are detected and corrected so as to improve overall safety. Furthermore, manual testing, which may interrupt power delivery, is avoided.

In this regard, in one exemplary aspect, a method of testing integrity for safety elements in a power distribution network configured to deliver power to remote elements is disclosed. The method comprises, during interrupt windows where a remote element decouples from a power conductor, testing an over current circuit in a power distribution circuit for integrity. The method also comprises testing a leakage current circuit in the power distribution circuit for integrity. The method also comprises testing a switch that decouples a power source from the power conductor in the power distribution circuit for integrity.

In another exemplary aspect, a method for testing integrity for an over current circuit in a power distribution network configured to deliver power to remote elements is disclosed. The method comprises, during interrupt windows where a remote element decouples from a power conductor, receiving a first voltage at an amplifier. The method also comprises receiving a second voltage at the amplifier. The method also comprises comparing an output of the amplifier to a reference value with a comparator. The method also comprises, when the output of the amplifier exceeds the reference value, providing an output to a latch circuit. The method also comprises detecting an output of the latch circuit with a management circuit.

In another exemplary aspect, a method for testing integrity for a leakage current circuit in a power distribution network configured to deliver power to remote elements is disclosed. The method comprises, during interrupt windows where a remote element decouples from a power conductor, receiving a first voltage at an amplifier. The method also comprises receiving a second voltage at the amplifier. The method also comprises comparing an output of the amplifier to a reference value with a comparator. The method also comprises, when the output of the amplifier exceeds the reference value, providing an output to a latch circuit. The method also comprises detecting an output of the latch circuit with a management circuit.

In another exemplary aspect, a method for testing integrity for a switch in a power distribution network configured to deliver power to remote elements is disclosed. The method comprises, during interrupt windows where a remote element decouples from a power conductor, injecting a test current. The method also comprises opening the switch. The method also comprises receiving a first voltage at an amplifier. The method also comprises receiving a second voltage at the amplifier. The method also comprises comparing an output of the amplifier to a reference value with a comparator. The method also comprises, when the output of the amplifier exceeds the reference value, providing an output to a latch circuit. The method also comprises, when the output of the amplifier does not exceed the reference value, providing no output to the latch circuit. The method also comprises detecting an absence of an output of the latch circuit with a management circuit.

In another exemplary aspect, a power distribution network with an integrity self test feature is disclosed. The power distribution network comprises a management circuit. The power distribution network also comprises an over current test circuit under control of the management circuit. The power distribution network also comprises a leakage current test circuit under control of the management circuit. The management circuit is configured to, during interrupt windows where a remote communication element decouples from a power conductor, test an over current circuit in a power distribution circuit for integrity. The management circuit is also configured to test a leakage current circuit in the power distribution circuit for integrity. The management circuit is also configured to test a switch that decouples a power source from the power conductor in the power distribution circuit for integrity.

In another exemplary aspect, a power distribution network with an over current self test circuit is disclosed. The power distribution network comprises an over current amplifier configured to receive a first voltage and a second voltage. The power distribution network also comprises an over current comparator coupled to an output of the over current amplifier and configured to compare a signal from the over current amplifier to a reference value. The power distribution network also comprises a latch circuit coupled to the over current comparator and configured to receive an output from the over current comparator when the signal from the over current amplifier exceeds the reference value. The power distribution network also comprises a management circuit coupled to an output of the latch circuit.

In another exemplary aspect, a power distribution network with a leakage self test circuit is disclosed. The power distribution network comprises a leakage amplifier configured to receive a first voltage and a second voltage. The power distribution network also comprises a leakage comparator coupled to an output of the leakage amplifier and configured to compare a signal from the leakage amplifier to a reference value. The power distribution network also comprises a latch circuit coupled to the leakage comparator and configured to receive an output from the leakage comparator when the signal from the leakage amplifier exceeds the reference value. The power distribution network also comprises a management circuit coupled to an output of the latch circuit.

In another exemplary aspect, a distributed communication system (DCS) is disclosed. The DCS comprises a central unit. The central unit is configured to distribute received one or more downlink communications signals over one or more downlink communications links to one or more remote subunits. The central unit is also configured to distribute received one or more uplink communications signals from the one or more remote subunits from one or more uplink communications links to one or more source communications outputs. The DCS also comprises a plurality of remote subunits. Each remote subunit comprises a power input port configured to be coupled to a power conductor and receive a power signal from a power source therefrom. Each remote subunit also comprises a switch coupled to the power input port. Each remote subunit also comprises a first power output port configured to be coupled to a second power conductor to provide power from the remote subunit to a second remote subunit. Each remote subunit also comprises a controller circuit. The controller circuit is configured to, during an interrupt window, open the switch to decouple the power conductor from the power source. The remote subunit is configured to distribute the received one or more downlink communications signals received from the one or more downlink communications links to one or more client devices. The remote subunit is also configured to distribute the received one or more uplink communications signals from the one or more client devices to the one or more uplink communications links. The DCS also comprises a power distribution network. The power distribution network comprises a management circuit. The power distribution network also comprises an over current test circuit under control of the management circuit. The power distribution network also comprises a leakage current test circuit under control of the management circuit. The management circuit is configured to, during interrupt windows where a remote communication element decouples from the power conductor, test an over current circuit in a power distribution circuit for integrity. The management circuit is also configured to test a leakage current circuit in the power distribution circuit for integrity. The management circuit is also configured to test a switch that decouples the power source from the power conductor in the power distribution circuit for integrity.

Additional features and advantages will be set forth in the detailed description which follows and, in part, will be readily apparent to those skilled in the art from the description or recognized by practicing the embodiments as described in the written description and claims hereof, as well as the appended drawings.

It is to be understood that both the foregoing general description and the following detailed description are merely exemplary and are intended to provide an overview or framework to understand the nature and character of the claims.

The accompanying drawings are included to provide a further understanding of the disclosure, and are incorporated in and constitute a part of this specification. The drawings illustrate one or more embodiment(s), and together with the description serve to explain principles and operation of the various embodiments.

### BRIEF DESCRIPTION OF THE DRAWINGS

FIG. 1 is a schematic diagram of an exemplary distributed communication system (DCS) in the form of a distributed antenna system (DAS) illustrating a power source delivering power to a subunit that is a remote antenna unit (RAU);

FIG. 2 is a schematic diagram of an exemplary data center illustrating a power source delivering power to a subunit that is a data server;

FIG. 3 is a schematic diagram of an exemplary distributed lighting system illustrating a power source delivering power to a subunit that is a remote lightning element;

FIG. 4 is a high level block diagram of a power distribution network embedded in a communication system, wherein the power distribution network includes a power source and a remote subunit that may communicate using exemplary aspects of the present disclosure;

FIG. 5 is a timing diagram of line voltage, current levels, and switch position during normal operation of a power distribution network in the absence of the present disclosure;

FIG. 6 is a simplified block diagram of the power distribution network of FIG. 4 abstracted outside of a radio communication system;

FIG. 7 is a simplified block diagram of the transmitter of the power distribution network of FIG. 6 with redundant safety elements illustrated;

FIG. 8 is a flowchart illustrating an exemplary process for monitoring safety elements in the power distribution network;

FIG. 9A is a schematic diagram illustrating a built in test (BIT) circuit for a negative line in a transmitter of a power distribution network such as the power distribution network of FIG. 6;

FIG. 9B is a larger version of the current sensor portions of the BIT circuit of FIG. 9A;

FIG. 10A is a timing diagram showing current and signal levels during an over current test cycle according to the BIT circuit of FIGS. 9A and 9B;

FIG. 10B is a flowchart illustrating a process for testing over current circuits consistent with the timing diagram of FIG. 10A;

FIG. 11A is a timing diagram showing current and signal levels during a leakage detection test cycle according to the BIT circuit of FIGS. 9A and 9B;

FIG. 11B is a flowchart illustrating a process for testing leakage current circuits consistent with the timing diagram of FIG. 11A;

FIG. 12A is a timing diagram showing current and signal levels during testing of a switch according to the BIT circuit of FIGS. 9A and 9B;

FIG. 12B is a flowchart illustrating a process for testing switches consistent with the timing diagram of FIG. 12A;

FIG. 13 is a diagram of another exemplary power distribution network that has cascaded remote units;

FIG. 14 is a flowchart illustrating the three integrity tests according to an exemplary aspect of the present disclosure;

FIG. 15 is a schematic diagram of an exemplary wireless distributed communication system (DCS) in the form of a distributed antenna system (DAS) that may have a power distribution network providing power from a central unit to remote antenna units;

FIG. 16 is a partially schematic cut-away diagram of an exemplary building infrastructure in which the DCS in FIG. 15 can be provided;

FIG. 17 is a schematic diagram of an exemplary optical-fiber based DCS configured to distribute communications signals between a central unit and a plurality of remote units, and that can include one or more power distribution networks, including the power distribution network in FIG. 4 configured to perform a line capacitance discharge of power conductors between a power source and a remote unit(s) when a safety disconnect of the power source is performed in response to a measured current from the connected power source when the remote unit is decoupled from the power source;

FIG. 18 is a schematic diagram of an exemplary mobile telecommunications environment that includes an exemplary radio access network (RAN) that includes a mobile network operator (MNO) macrocell employing a radio node, a shared spectrum cell employing a radio node, an exemplary small cell RAN employing a multi-operator radio node located within an enterprise environment as DCSs, and that can include one or more power distribution networks, including the power distribution networks in FIGS. 4, 16, and 17, configured to perform a line capacitance discharge of power conductors between a power source and a remote unit(s) when a safety disconnect of the power source is performed in response to a measured current from the connected power source when the remote unit is decoupled from the power source;

FIG. 19 is a schematic diagram an exemplary DCS that supports 4G and 5G communications services, and that can include one or more power distribution networks, including the power distribution networks in FIGS. 4 and 16-18, configured to perform a line capacitance discharge of power conductors between a power source and a remote unit(s) when a safety disconnect of the power source is performed in response to a measured current from the connected power source when the remote unit is decoupled from the power source; and

FIG. 20 is a schematic diagram of a generalized representation of an exemplary controller that can be included in any component or circuit in a power distribution network, including the power distribution networks in FIGS. 4 and 16-19, that is configured to perform a line capacitance discharge of power conductors between a power source and a remote unit(s) when a safety disconnect of the power source is performed in response to a measured current from the connected power source when the remote unit is decoupled from the power source, wherein an exemplary computer system is adapted to execute instructions from an exemplary computer readable link.

### DETAILED DESCRIPTION

Exemplary aspects of systems and methods for integrity checks for safety features in a power distribution network are disclosed. In particular, the integrity of circuit breakers used in an operating protection system as well as the integrity of current sensors may be checked. In a specific exemplary aspect, such a check may include testing the ability of individual switches to disconnect, testing the correctness of a leakage current sensor reading, and testing the correctness of an over current sensor reading. To perform these tests, an individual element is isolated and provided a test current. Any alarms generated by the element under test are diverted or suppressed so that operation (i.e., power distribution) continues normally. The safety features remain intact during testing by virtue of the redundant circuits not being tested simultaneously. Testing the safety power elements ensures that faults in the systems are detected and corrected so as to improve overall safety. Furthermore, manual testing, which may interrupt power delivery, is avoided.

In effect, by providing a built in test (BIT) apparatus and procedure, a self-test feature allows the integrity of the overall system to be monitored in essentially real time through frequent monitoring. The ability to test while the system is in operation eliminates the need to stop operation of the communication system for testing of the integrity of the protection circuits. Further, fault recognition is performed in a small time period. As noted, manual testing may be avoided thereby reducing maintenance costs while improving the overall reliability of the safety system at minimal additional cost.

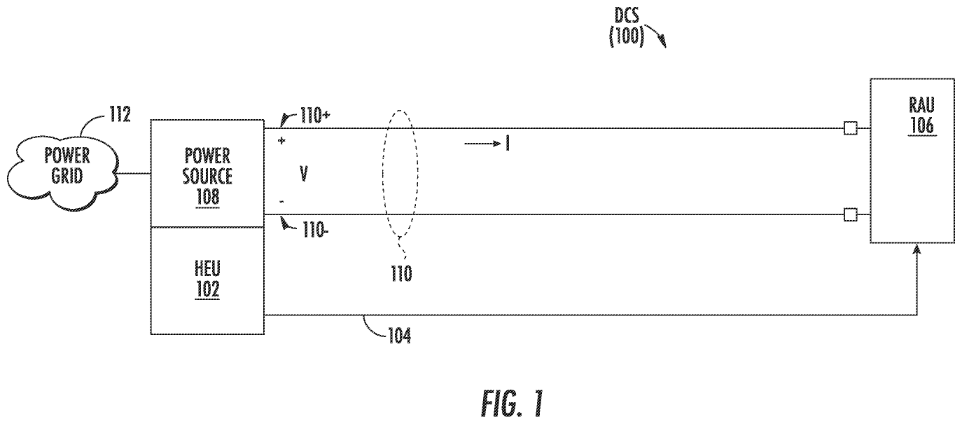

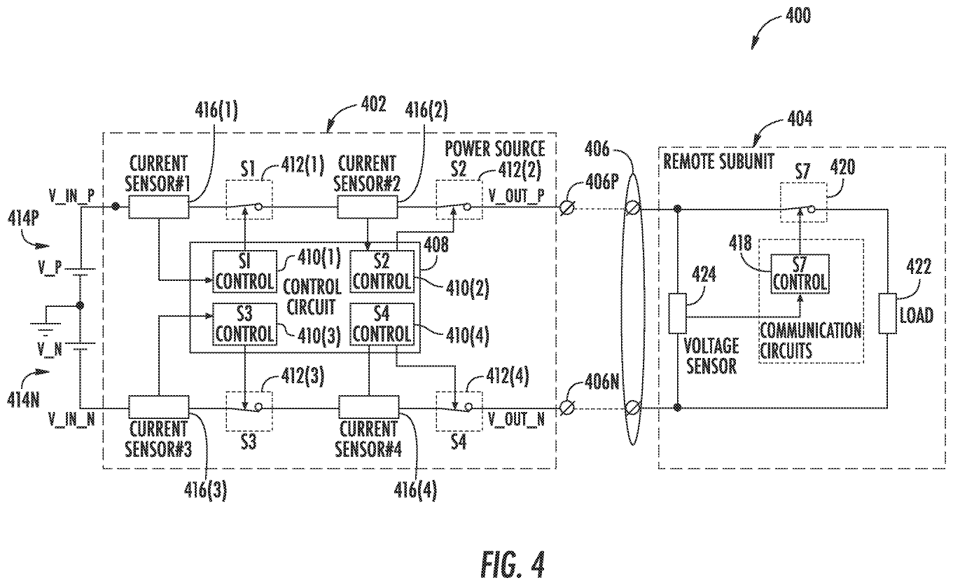

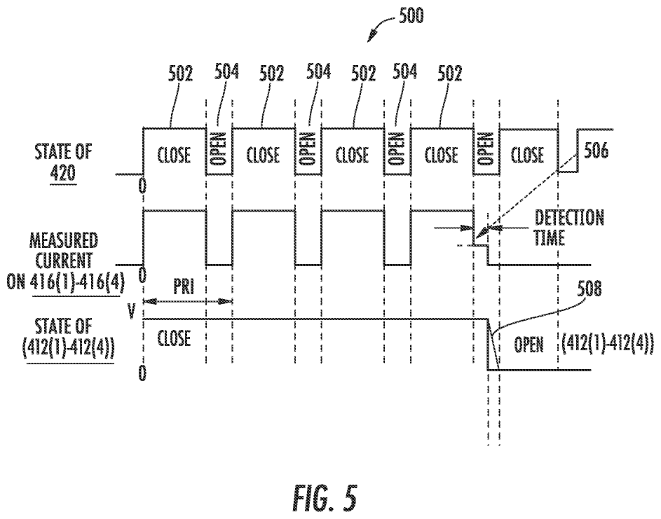

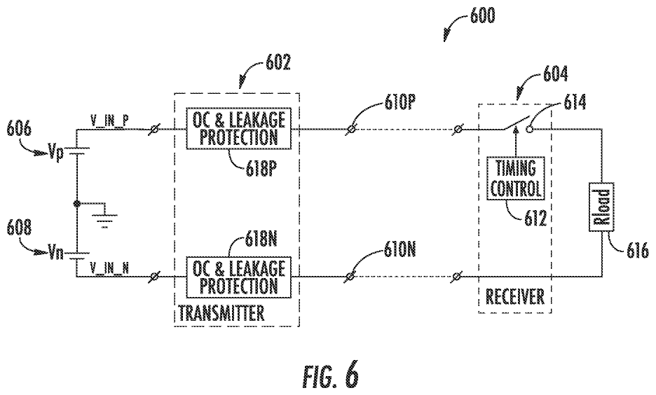

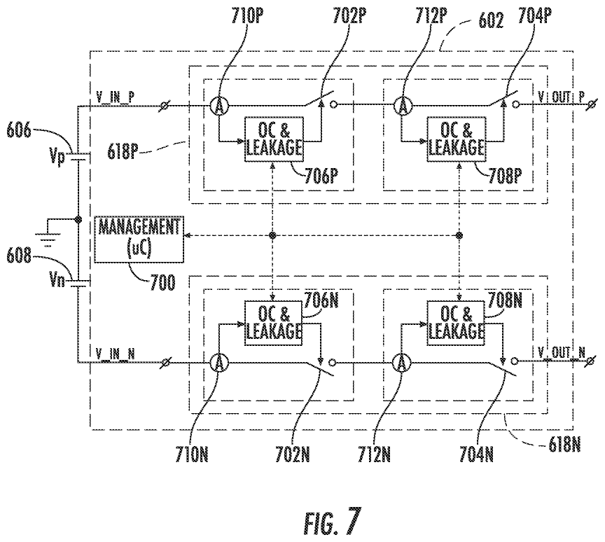

A power distribution network rarely exists in isolation. Rather, a power distribution network provides infrastructure to some other system, a few of which are briefly discussed with reference to FIGS. 1-3. A more detailed discussion of a power distribution network with safety features is provided with reference to FIG. 4 and FIG. 5. A discussion of exemplary aspects of the integrity checks begins below at FIG. 6.

In this regard, FIG. 1 illustrates a block diagram of a distributed communication system (DCS) 100. The DCS 100 may include a head end unit (HEU) 102 that communicates through a communication medium 104 with a remote antenna unit (RAU) 106. The communication medium 104 may be a wire-based or optical fiber medium. The RAU 106 includes a transceiver and an antenna (not illustrated) that communicate wirelessly with mobile terminals and other user equipment (also not illustrated). Because the RAU 106 sends and receives wireless signals and may potentially perform other functions, the RAU 106 consumes power. That power may, in some instances, be provided locally. More commonly, the RAU 106 receives power from a power source 108 that transmits power to the RAU 106 over power lines 110 formed from a positive power line 110+ and a negative power line 110−. The power lines 110 may be many meters long, for example, extending through an office building, across multiple floors of a multi-story building, or the like. Further, the power lines 110 may couple to multiple RAUs 106 (even though only one is illustrated in FIG. 1). The power source 108 may be coupled to an external power grid 112.

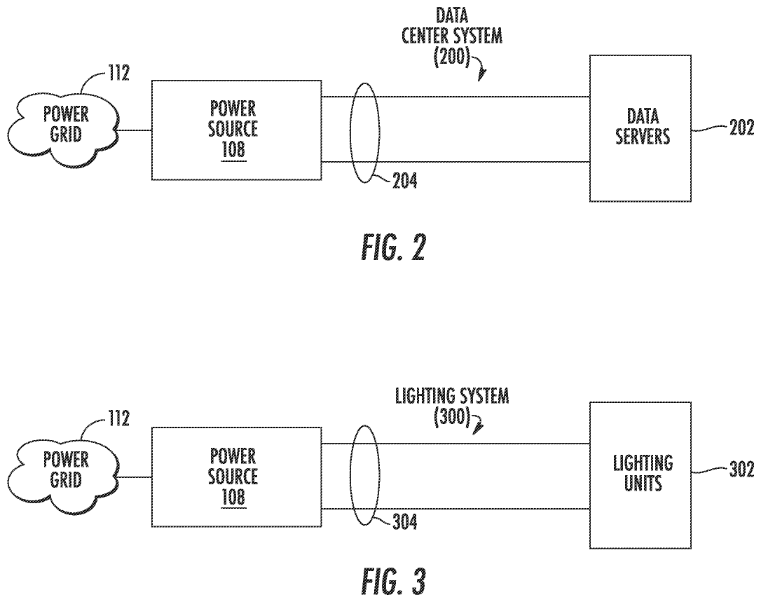

Similarly, FIG. 2 illustrates a data center system 200 having a power source 108 coupled to remote data servers 202 through power lines 204. The power source 108 is coupled to the external power grid 112. As with the RAU 106, the data servers 202 may consume power supplied through the power lines 204.

Similarly, FIG. 3 illustrates a lighting system 300 having a power source 108 coupled to remote lighting units 302 through power lines 304. The power source 108 is coupled to the external power grid 112. As with the RAU 106, the remote lighting units 302 may consume power supplied through power lines 304.

It should be appreciated that there may be other contexts that may use a power distribution network and the examples provided in FIGS. 1-3 are not intended to be limiting. As a note of nomenclature, the RAU 106, the remote data servers 202, and the lighting units 302 are sometimes referred as remote units, remote elements, or even remote subunits in that they are subunits of the entirety of the power distribution network.

The present disclosure provides a way for safety elements within a power distribution network to be tested while the power distribution network is actively delivering power to remote subunits. Before addressing exemplary aspects of the safety feature integrity checks of the present disclosure, a more detailed discussion of a power distribution network that is designed to provide power to a load in a remote subunit while having appropriate power safety elements is provided. Thus, depending on the nature of the associated system, the loads may be macrocells, remote units, RAUs, RANs, shared spectrum cells that use licensed or unlicensed bandwidth, small cell radio nodes, head end units, remote radio units, remote radio heads, cameras, lighting elements, servers, or other electrical power consuming devices.

In this regard, FIG. 4 provides a block diagram of a power distribution network 400 capable of effectuating communication between a power source 402 and a remote subunit 404. The power source 402 is coupled to the remote subunit 404 through power conductors 406. The power conductors 406 may include a positive power conductor 406P and a negative power conductor 406N. The power source 402 may include a controller circuit 408 with optional sub circuits 410(1)-410(4) configured to control switches 412(1)-412(4) that connect power supplies 414P and 414N to the power conductors 406P and 406N, respectively. Current sensors 416(1)-416(4) may be provided in the power source 402. The current sensors 416(1)-416(4) may be used to detect unsafe operating conditions. It is these switches 412(1)-412(4) and current sensors 416(1)-416(4) that are tested to verify that they are operating correctly.

With continued reference to FIG. 4, the remote subunit 404 may include a control circuit 418 that controls a switch 420. The switch 420 may decouple a load 422 from the power conductors 406. A voltage sensor 424 may be provided that monitors the voltage levels on the power conductors 406 and reports the same to the control circuit 418.

In operation, the remote subunit 404 opens and closes the switch 420 to decouple the load 422 periodically, thereby interrupting current supplied to the load 422 while leaving the voltage on the power conductors 406 high. A timing diagram 500 is provided in FIG. 5 that illustrates operating of the switch 420 and the corresponding changes in current measured on the power conductors 406. Opening and closing of the switch 420 creates power transfer windows 502 (sometimes referred to as a power transfer period) and power interrupt windows 504 (sometimes referred to as a power interrupt period). Collectively a single power transfer window 502 and an adjacent power interrupt window 504 have a period that is termed herein a “pulse repetition interval” or “PRI.” The power source 402 may monitor current on the power conductors 406 with the current sensors 416(1)-416(4) to make sure that the power interrupt windows 504 occur. If current is detected during a power interrupt window 504 (e.g., at 506 in FIG. 5), the controller circuit 408 may infer that an external load such as a human is touching the power conductor(s) 406 creating an unsafe situation. Accordingly, the controller circuit 408 may open one or more of the switches 412(1)-412(4) to disconnect the power conductors 406 from the power source 402 as shown at 508 in FIG. 5.

As different remote subunits 404 may have minor differences in the rate with which the switch 420 is activated by the control circuit 418, the power source 402 may initially synchronize to the timing generated by the remote subunit 404. A synchronization process may run in the background and may halt only during data transfers. In essence, the synchronization process allows the power source 402 to learn the switching rate of the remote subunit 404 and “know” when to expect a power interrupt window 504 by the remote subunit 404.

As will be explained in greater detail beginning with reference to FIG. 6, exemplary aspects of the present disclosure test the switches 412(1)-412(4) and the current sensors 416(1)-416(4) that are used to provide the safety features described in FIG. 4.

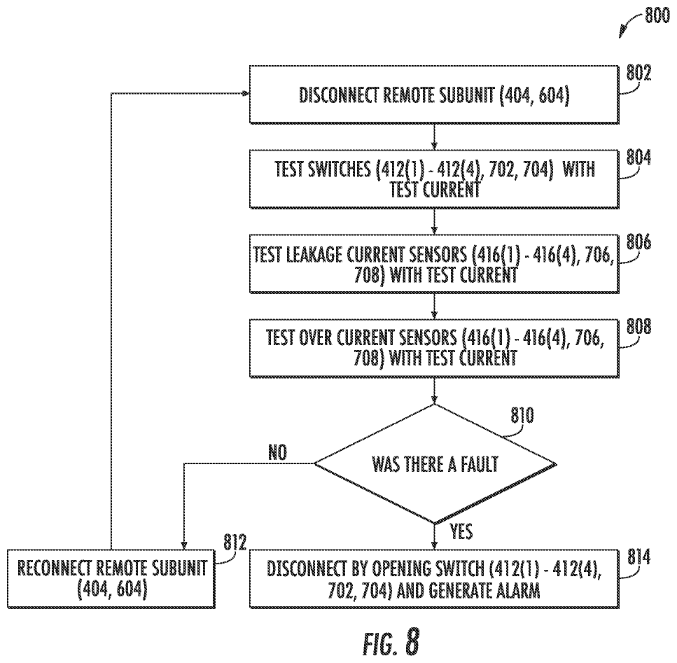

In this regard, FIG. 6 shows a simplified version of a power distribution network 600. The power distribution network 600 has a transmitter 602 that may be in the power source 402 of FIG. 4 and a receiver 604 corresponding to the remote subunit 404. The transmitter 602 receives a first signal V_IN_P from a positive power source 606 (also referred to as Vp in FIG. 6) and a second signal V_IN_N from a negative power source 608 (also referred to as Vn in FIG. 6). A positive conductor 610P and a negative conductor 610N couple the transmitter 602 to the receiver 604. A timing control circuit 612 in the receiver 604 opens and closes a receiver switch 614 (analogous to the switch 420) periodically or according to other commands. When the receiver switch 614 is open, a load 616 (also referred to as Rload in FIG. 6) is disconnected or decoupled from the transmitter 602. The transmitter 602 further has a positive over current (OC) and leakage protection circuit 618P and a negative OC and leakage protection circuit 618N. The transmitter 602 outputs signals V_OUT_P onto the positive conductor 610P and V_OUT_N onto the negative conductor 610N (shown in FIG. 7).

Progressively more detail of the transmitter 602 is provided in FIG. 7, where a management circuit 700 (also referred to as a control circuit and/or a microcontroller (μC)) provides control signals to control the positive OC and leakage protection circuit 618P and the negative OC and leakage protection circuit 618N. To reduce the impact of a safety feature failure, exemplary aspects of the present disclosure provide for redundancy in the positive OC and leakage protection circuit 618P and the negative OC and leakage protection circuit 618N. Specifically, the positive OC and leakage protection circuit 618P includes a first switch 702P and a second switch 704P (analogous to the switches 412(1)-412(2) of FIG. 4) while the negative OC and leakage protection circuit 618N includes a first switch 702N and a second switch 704N (analogous to the switches 412(3)-412(4) of FIG. 4). Likewise, the positive OC and leakage protection circuit 618P includes a first OC and leakage sensor 706P and a second OC and leakage sensor 708P, while the negative OC and leakage protection circuit 618N includes a first OC and leakage sensor 706N and a second OC and leakage sensor 708N. Additionally, ammeters (A) formed by shunt resistors 710P, 712P are provided for the positive OC and leakage protection circuit 618P while ammeters (A) formed by shunt resistors 710N, 712N are provided for the negative OC and leakage protection circuit 618N.

An overview of the method for checking integrity of safety elements is provided in FIG. 8 which illustrates, through a flowchart, process 800, which begins when the remote subunit 404, 604 disconnects (block 802) by opening its switch 420 or 614. The controller circuit 408 (or other control circuit) tests switches 412(1)-412(4), 702, 704 with a test current (block 804). The controller circuit 408 (or other control circuit) tests leakage current sensors 416(1)-416(4), 706, 708 within the current measurement circuit with a test current (block 806). The controller circuit 408 (or other control circuit) tests over current sensors 416(1)-416(4), 706, 708 within the current measurement circuit with a test current (block 808). The controller circuit 408 determines if there was a fault (block 810) in any of the blocks 804, 806, or 808. If the answer is no, then the remote subunit 404, 604 reconnects (block 812) and the system continues to operate in normal mode. If there was a fault at block 810, then the controller circuit 408 may open the switches 412(1)-412(4), 702, 704 and generate an alarm (block 814). Note that because the remote subunit 404, 604 operates independently from the controller circuit 408, the remote subunit 404, 604 may reconnect to the power conductors (not shown in the process 800) even though there is no power being provided thereover once the switches 412(1)-412(4), 702, 704 are opened. Note that the order of the testing may be varied without departing from the scope of the present disclosure. Likewise, the frequency of the testing may be varied. In an exemplary aspect, the testing is done once a second. In another exemplary aspect, at least a portion of testing is done during every window in which the remote subunit 404, 604 is decoupled from the power conductors 406, 610. Other testing frequencies may be employed without departing from the present disclosure.

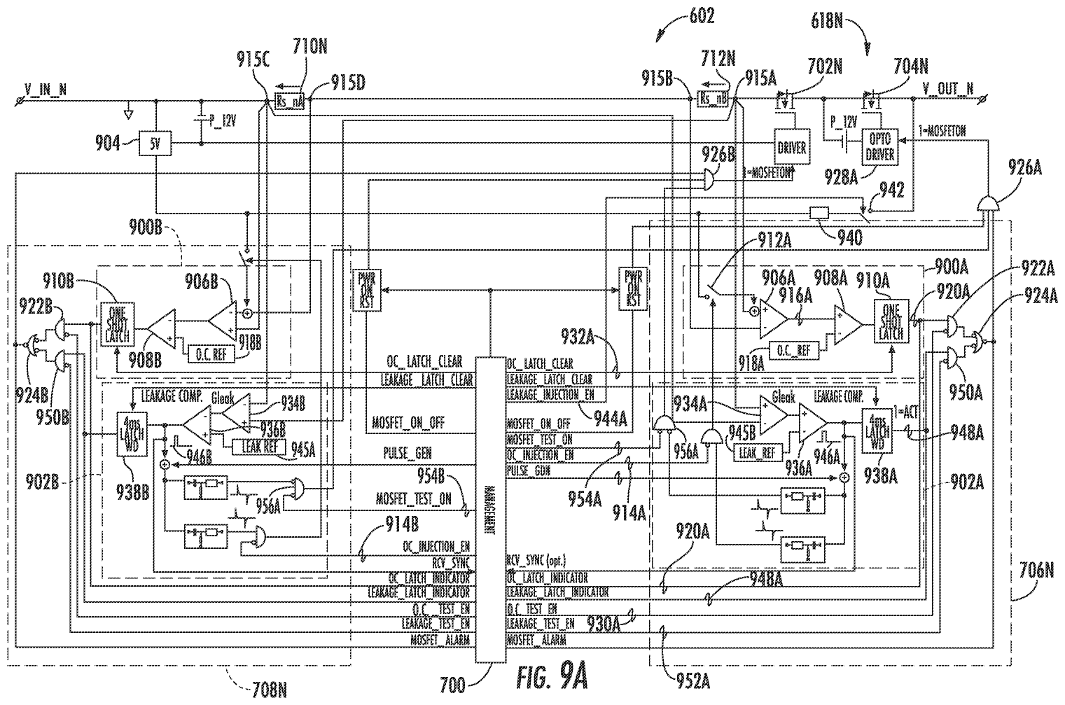

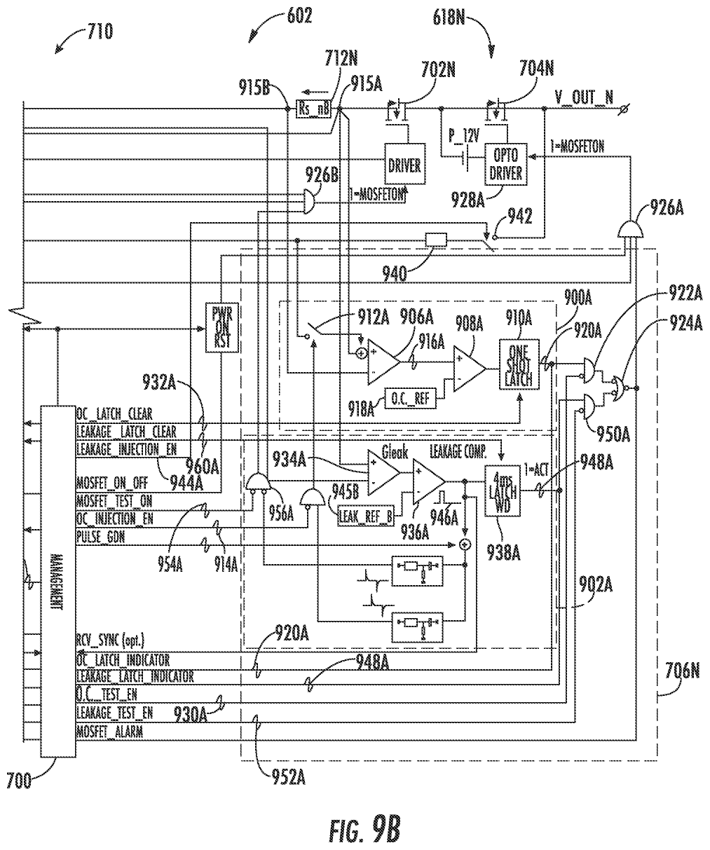

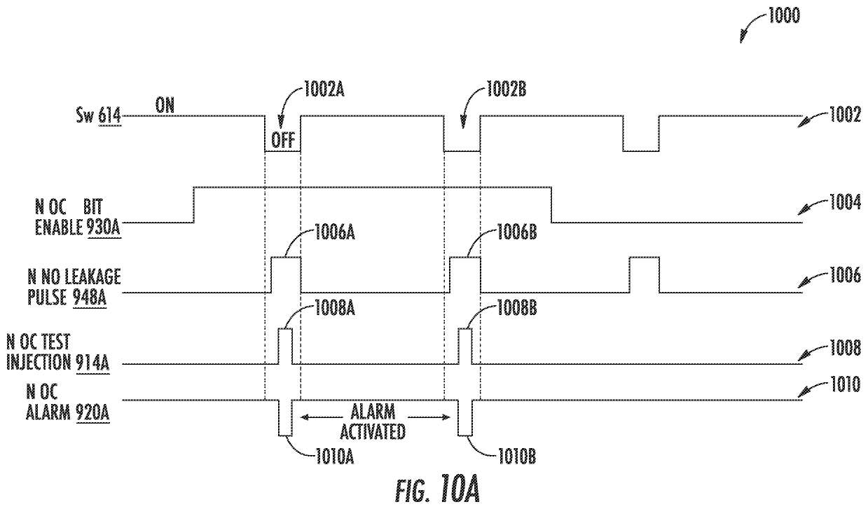

To assist in fault detection, each of the elements (primary and redundant or back-up) of the positive OC and leakage protection circuit 618P and the negative OC and leakage protection circuit 618N must be tested. The primary way to test each element is through the use of a test current. However, just sending a test current through the elements may result in false alarms as current may be detected by protection elements at times when there should be no current flow (e.g., because the receiver 604 is disconnected). FIGS. 9A and 9B provide a still more detailed view of the transmitter 602 and particularly of the negative OC and leakage protection circuit 618N with the understanding that the positive OC and leakage protection circuit 618P is substantially similar. FIG. 9B is an enlarged version of the right half of FIG. 9A to assist in viewing the elements that are otherwise rather small in FIG. 9A.

With reference to FIGS. 9A and 9B, the negative OC and leakage protection circuit 618N includes the first switch 702N and the second switch 704N in the form of transistors as well as the first OC and leakage sensor 706N and the second OC and leakage sensor 708N. Further, shunt resistors 710N, 712N are provided (also labeled Rs_nA and Rs_nB). While the shunt resistors 710N, 712N are placed at specific points in FIG. 7, it should be appreciated that an ammeter (shunt resistor) can be placed in any place along the P/N branches. Within the first OC and leakage sensor 706N are a first over current circuit 900A and a first leakage current circuit 902A. Within the second OC and leakage sensor 708N are a second over current circuit 900B and a second leakage current circuit 902B. A test current is provided by a voltage source 904, which in an exemplary aspect provides five volts (5 V) to produce the test current. A ground (GND) is provided proximate the voltage source 904.

Beginning with the first over current circuit 900A, exemplary aspects of the present disclosure use an over current test circuit to test the shunt resistors 710N, 712N, an amplifier 906A, a comparator 908A, and a one-shot latch 910A, also referred to as a latch circuit or one-shot latch circuit. In particular, the management circuit 700 connects the voltage source 904 using a variety of switches as explained further below. In an exemplary aspect, the voltage source 904 is an existing voltage source, but could be dedicated for the transmitter 602. The management circuit 700 also closes a switch 912A within the first over current circuit 900A using a signal 914A (also referred to as an overcurrent injection enable (OC_INJECTION_EN) signal). Closing the switch 912A connects the voltage source 904 to the amplifier 906A and thus injects a test voltage (which is designed to be equivalent to the voltage generated by the load current (the current when a normal load 616 is connected to the transmitter 602) on the shunt resistor 712N) into the input of the amplifier 906A. It should be appreciated that the amplifier 906A receives voltages from both the upward or upstream side 915A and the downward or downstream side 915B of the shunt resistor 712N. Note that when the second over current circuit 900B is tested, the upward side 915C of the shunt resistor 710N and the downward side 915D of the shunt resistor 710N are used to feed values to the amplifier 906B. Returning to the first over current circuit 900A, the differential signal formed at the two inputs of the amplifier 906A is then amplified by the amplifier 906A. Assuming that there is no current across the shunt resistor 712N, the only signal that is amplified is the injected test signal. The amplified signal 916A is provided to the comparator 908A, which compares the amplified signal 916A to an over current reference value provided by circuit 918A. The current present at the upward side 915A should be zero to avoid inaccuracy (assuming no external load). However, because the test signal is present, and because the test signal should be higher than the threshold, the comparator 908A will output a signal to the one-shot latch 910A. The one-shot latch 910A outputs a signal 920A that is provided to the management circuit 700 and to an AND gate 922A, which in turn provides an output to a NOR gate 924A. The NOR gate 924A is coupled to an AND gate 926A, which in turn provides an on/off signal to a driver 928A for the second switch 704N.

In normal operation (i.e., not during a test), the arrival of the signal 920A from the one-shot latch 910A at the driver 928A is indicative of an over current situation. To prevent the signal 920A from being passed to the NOR gate 924A, the management circuit 700 may send a signal 930A (also labeled OC_TEST_EN) to the AND gate 922A. The signal 930A effectively turns off the AND gate 922A, which blocks delivery of the signal 920A to the NOR gate 924A. Since the management circuit 700 knows that it should expect the signal 920A as a result of the injected voltage during the interrupt window from the one-shot latch 910A, the management circuit 700 can treat the test as a success and ignore the alarm that is implicit in the arrival of the signal 920A. Finally, a signal 932A is sent from the management circuit 700 to clear the one-shot latch 910A and the signal 930A is deasserted. If no signal 920A is received at the management circuit 700, then the management circuit 700 may determine that the over current circuit 900A has a failure and generate an appropriate alarm and/or indicate a service call is appropriate. While the first over current circuit 900A is being tested, the second over current circuit 900B remains active and able to test for a normal over current condition.

The second OC and leakage sensor 708N (only illustrated in FIG. 9A) is substantially similar to the first OC and leakage sensor 706N with corresponding elements differentiated by a “B” label (e.g., the amplifier 906B, comparator 908B, etc.). It should further be appreciated that the first and second OC and leakage sensors 706P and 708P are likewise substantially similar allowing for the differences between positive conductor lines and negative conductor lines as is well understood.

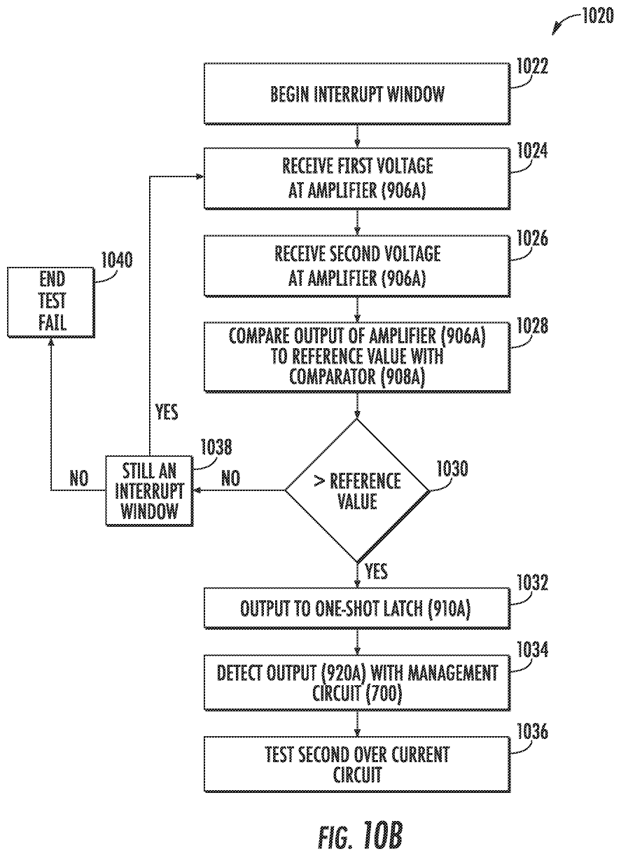

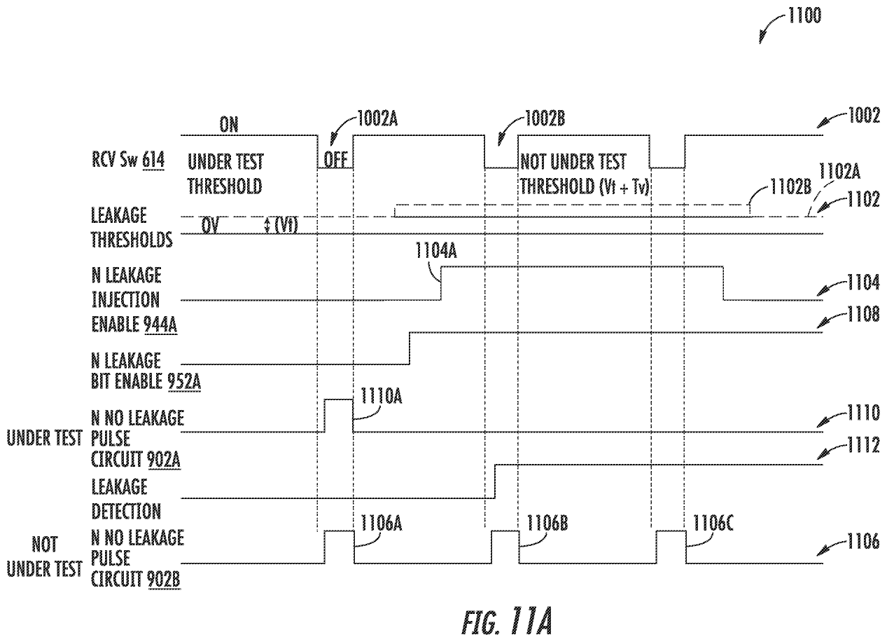

An overview of the current levels and signals of the over current circuit 900A is provided in timing diagram 1000 of FIG. 10A while FIG. 10B shows a flowchart illustrating a process 1020 associated with testing the over current circuit 900A. In particular, the activity of the receiver switch 614 of FIG. 6 is provided on the first row 1002. When the receiver switch 614 is “on,” current flows across the power conductors 406P, 406N, 610P, 610N and power is supplied to the receiver 404, 604. As noted, the receiver 604 periodically opens the receiver switch 614 (i.e., turns it “off”) as indicated at 1002A, 1002B, etc. The times 1002A, 1002B, etc. when the receiver switch 614 is off are referred to as the interrupt windows or interrupt periods. In an exemplary aspect, the interrupt window is 0.5 ms and the connection window is 3.5 ms. The signal 930A is illustrated in the second row 1004, where the over current test is enabled across multiple interrupt periods and the AND gate 922A is turned off. Normal leakage testing continues to occur as evidenced by third row 1006 where no leakage pulses 1006A, 1006B, etc. are reported by a signal 948A of a timed latch 938A, also referred to as a latch circuit or timed latch circuit. However, when the test voltage is injected, and the switch 912A is enabled as illustrated by the signal 914A in the fourth row 1008 at times 1008A, 1008B, etc., the one-shot latch 910A generates signal 920A, shown in the fifth row 1010. An alarm would normally activate at time 1010A and is cleared by signal 932A (not shown in FIG. 10A). An additional alarm may be generated at time 1010B (and again be cleared by signal 932A, still not shown in FIG. 10A). However, because signal 930A is active, no alarm is generated and nothing turns off the switches 702N, 704N, and the management circuit 700 concludes that the over current circuit 900A is operational.

Turning to FIG. 10B, the process 1020 associated with testing the over current circuit 900A begins with an interrupt window (block 1022) (e.g., 1002A). The amplifier 906A is a difference amplifier and receives a first voltage (block 1024) such as the voltage at the upstream side 915A of the shunt resistor 712N. The amplifier 906A receives a second voltage (block 1026) such as the voltage at the downstream side 915B of the shunt resistor 710N. The amplifier 906A amplifies the differential signal and provides an output to the comparator 908A. The comparator 908A compares the output of the amplifier 906A to a reference value (block 1028) from circuit 918A. When the output of the amplifier 906A exceeds the reference value from the circuit 918A (block 1030), the comparator 908A provides an output to the one-shot latch 910A (block 1032). The management circuit 700 detects the output signal 920A of the one-shot latch 910A (block 1034). The process 1020 continues by testing a second over current circuit (block 1036). Note that the process 1020 may be spread out over a series of interrupt windows. Thus, block 1036 may take place at a subsequent interrupt window than the original interrupt window of block 1022. Note that if the output of the amplifier 906A does not exceed the reference value at block 1030, then the management circuit 700 may determine if there is still an interrupt window (block 1038). If the answer is no, then the management circuit 700 may end the test and indicate a failure (block 1040) since there was no indication that the test voltage was detected.

In contrast to the over current circuit 900A which tests whether the elements that detect an over current situation which would potentially damage the power source, a leakage current test circuit tests the first leakage current circuit 902A to determine whether there is any leakage current in the power distribution network 600 that would be indicative of an external load. Again, it should be appreciated that only one side is tested at a time so that the other side can detect a real leakage current situation. The first leakage current circuit 902A includes the shunt resistors 710N, 712N, an amplifier 934A, a comparator 936A, and the timed latch 938A (which in this case is 4 ms corresponding to an exemplary PRI). In particular, the leakage current test is based on an injection of a test current by passing a current through a resistor 940 and a closed switch 942. The switch 942 is closed by a leakage injection enable signal 944A from the management circuit 700. Because the leakage current will go to both leakage current circuits 902A, 902B when the switch 942 is closed, to avoid a false alarm, the threshold of the side not under test is increased by using a leakage reference circuit 945A, 945B in conjunction with the opposite comparator 936A, 936B (i.e., the leakage reference circuit 945B is coupled to the comparator 936A and the leakage reference circuit 945A is coupled to the comparator 936B). While not shown in FIG. 9A or 9B, it should be appreciated that the management circuit 700 may send a signal (also not shown) to the respective leakage reference circuit depending on which side is being tested. For the side that is not under test, the appropriate leakage reference circuit 945A, 945B provides a value equal to the sum of the original threshold value and the value created by the voltage source 904 and the resistor 940. For the side under test, the injected test current will emulate the leakage and be detected by the amplifier 934A. In particular, the amplifier 934A (which is also a difference amplifier) receives a signal from the upward side 915A of the shunt resistor 712N and a signal from the downward side 915D of the shunt resistor 710N. The difference between these signals is amplified by the amplifier 934A. Similarly, the amplifier 934B receives the same two signals. The amplified signal from the amplifier 934A is compared to the threshold value by the comparator 936A. Because this side is under test, the leakage reference circuit 945B is not active. The comparator 936A will output a signal 946A to the timed latch 938A. The timed latch 938A, having received a pulse during the interrupt window, will output a signal 948A, which is passed to the management circuit 700 and to an input of an AND gate 950A. The AND gate 950A is coupled to the NOR gate 924A. The AND gate 950A also receives a signal 952A from the management circuit 700. The AND gate 950A is the alarm generator circuit. However, the signal 952A from the management circuit 700 prevents the AND gate 950A from generating an alarm during the testing phase. However, as the leakage current circuit 902B is not under test, its corresponding AND gate 950B may still generate an alarm if a leakage current in excess of the elevated threshold (the injected test current plus the original leakage current signal) is detected. If the timed latch 938A does not trip, then there is a fault in the leakage current circuit 902A and an alarm may be generated. If, however, the timed latch 938A did trip, then the test was satisfied, the switch 942 is opened while the timed latch 938A is cleared, the reference circuit 945A (i.e., the circuit for the side not under test) is set by the management circuit 700 to its default value, and normal operation resumes.

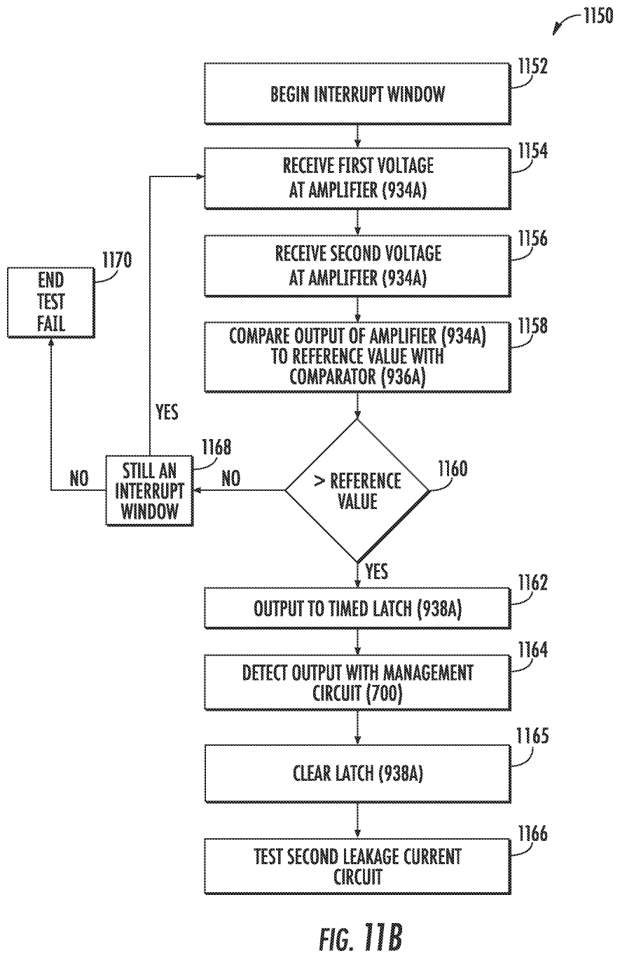

An overview of the current levels and signals of the leakage current circuit 902A is provided in timing diagram 1100 of FIG. 11A. In particular, the activity of the receiver switch 614 of FIG. 6 is provided on the first row 1002. When the receiver switch 614 is “on,” current flows across the power conductors 610N, 610P and power is supplied to the receiver 604. As noted, the receiver 604 periodically opens the receiver switch 614 (i.e., turns it “off”) as indicated at 1002A, 1002B, etc. The second row 1102 shows the adjustment of the threshold values. Normally, the leakage threshold is some small value Vt as shown by the second row 1102. That is, if current is detected above Vt, it is generally assumed that there is an improper short on the conductors. While Vt could be zero, there may be noise on the conductors, which makes a higher value more appropriate. However, the nature of the leakage test is to send a known current through the leakage sensors and generate an alarm if the leakage sensors do not detect the expected current induced by the injected known current. To avoid a false positive, the side not under test must have its detection threshold adjusted. Thus, during a test, as indicated by the assertion 1104A of the leakage injection enable signal 944A (turning on switch 942) in row 1104, the threshold of the side not under test (e.g., circuit 902B) is elevated to 1102B corresponding to Vt plus some known test value Tv. Meanwhile, the threshold 1102A for the side under test (e.g., circuit 902A) remains at Vt (i.e., the original threshold value). The leakage injection enable signal 944A may be asserted only after the threshold is elevated to 1102B and may be deasserted before the threshold is lowered back to 1102A to avoid a false positive. In this fashion, the side not under test (e.g., 902B) will generate the expected no leakage pulses 1106A, 1106B, 1106C.

Row 1108 illustrates signal 952A from the management circuit 700 to the AND gate 950A. Since the AND gate 950A is the alarm generator circuit, use of the signal 952A from the management circuit 700 prevents the AND gate 950A from generating an alarm during the testing phase. Row 1110 represents the no leakage pulse signal from the circuit 902A (i.e., the device under test), and is, as illustrated, asserted 1110A in the first interrupt window 1002A (i.e., before the test starts), but not present in subsequent interrupt windows 1002B, etc. (i.e., while the test is occurring). Row 1112 illustrates the signal of leakage detection. Specifically, this signal is detected by the management circuit 700 and shows that the leakage detection circuit detected the test leakage current. If no leakage signal was detected during the test, the management circuit 700 concludes that the leakage detection circuit is damaged and will disconnect the power conductor 406 and the remote subunit 404 from the power source 414 by opening switches 412(1)-412(4).

The process 1150 for testing the leakage current circuit 902A is provided as a flowchart in FIG. 11B. In this regard, the process 1150 begins with an interrupt window (block 1152) (e.g., 1002A). The amplifier 934A receives a first voltage (block 1154) such as at the upstream side 915A of the shunt resistor 712N. The amplifier 934A receives a second voltage (block 1156) such as at the downstream side 915D of the shunt resistor 710N. The amplifier 934A amplifies the differential signal and provides an output to the comparator 936A. The comparator 936A compares the output of the amplifier 934A to a reference value (block 1158) from circuit 944B. When the output of the amplifier 934A exceeds the reference value from the circuit 944B (block 1160), the comparator 936A provides an output to the timed latch 938A (block 1162). The management circuit 700 detects the signal 948A of the timed latch 938A (block 1164) and the latch 938A is cleared (block 1165). The process 1150 continues by testing a second leakage current circuit (block 1166). Note that the process 1150 may be spread out over a series of interrupt windows. Thus, block 1166 may take place at a subsequent interrupt window than the original interrupt window of block 1152. Note that if the output of the amplifier 934A does not exceed the reference value at block 1160, then the management circuit 700 may determine if there is still an interrupt window (block 1168). If the answer is no, then the management circuit 700 may end the test by indicating a fail (block 1170) and generating an alarm.

The circuitry to perform the test of the switches 702N and 704N is also shown in FIGS. 9A and 9B. In particular, the test current is supplied by the voltage source 904 during an interrupt period. The switch 702N or 704N under test will be opened so as to create a “no leakage pulse” at the appropriate leakage current circuit 902A, 902B. If the associated leakage current circuit 902A, 902B does not detect a no leakage condition, then the switch 702N, 704N is not able to open and an alarm is generated. To do this, the switch 942 is closed, the voltage source 904 is connected, and the test current is activated. The reference level in the leakage reference circuit 945A is increased to avoid a false alarm in the untested circuit. As with the leakage current test, the increment in value should be proportional to the injected current. The leakage enable signal 952A is generated by the management circuit 700 to prevent a false activation of the switches 702N, 704N. A signal 954A is generated by the management circuit 700, which allows a switching signal from an AND gate 956A. Alternatively, the signal 954A may be generated by the management circuit 700 synchronously to the power interrupt window. The signal 948A from the timed latch 938A is also sampled by the management circuit 700. A decision is made by the management circuit 700 whether the switch being tested is operational and whether future system operation is safe. The leakage current injection is then turned off by the management circuit 700 (i.e., by disconnecting the voltage source 904 or opening switch 942). The leakage current threshold value of the untested circuit is set back to its default value and the timed latch 938A is cleared by signal 960A.

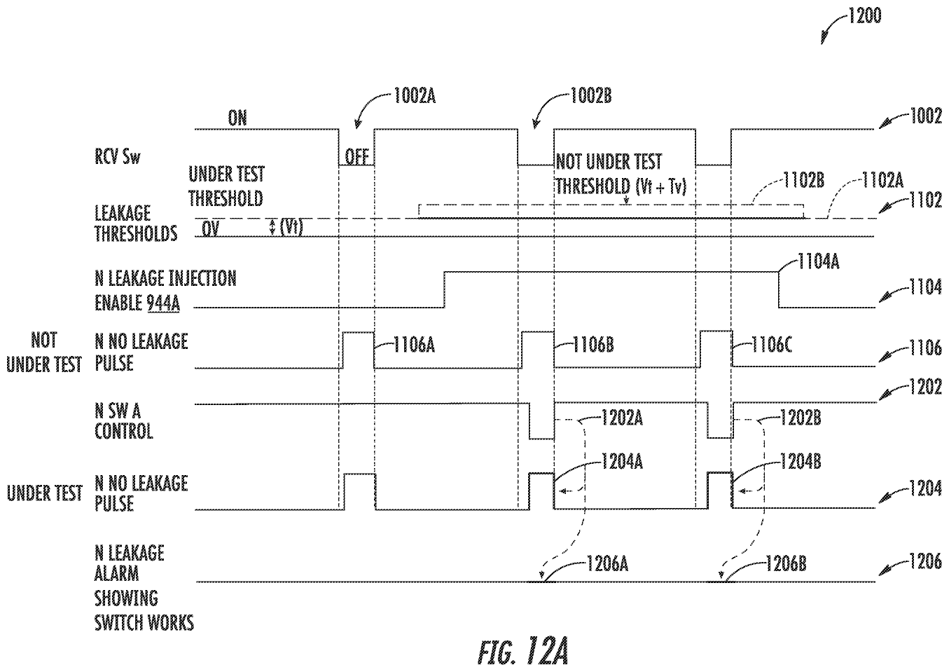

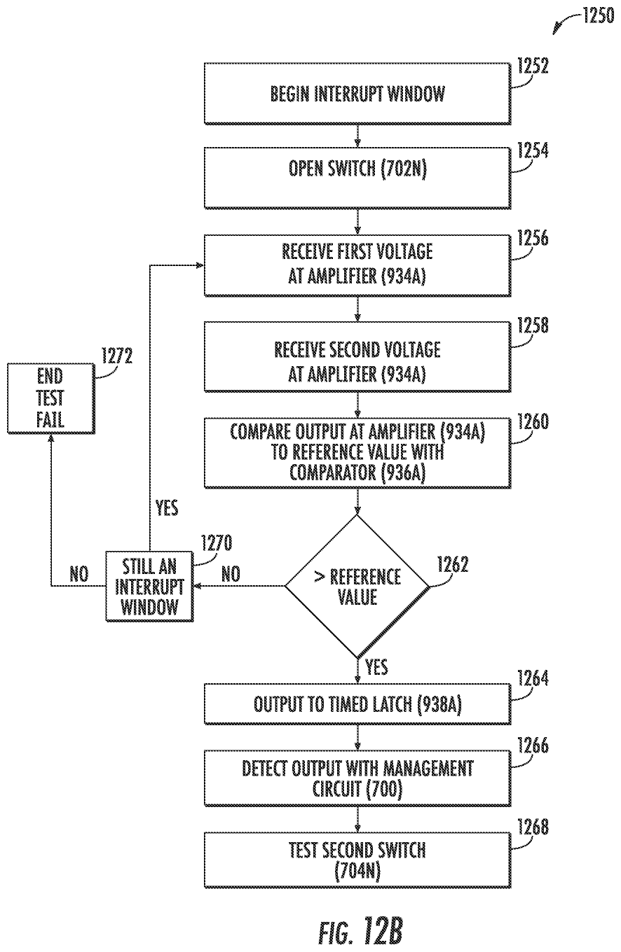

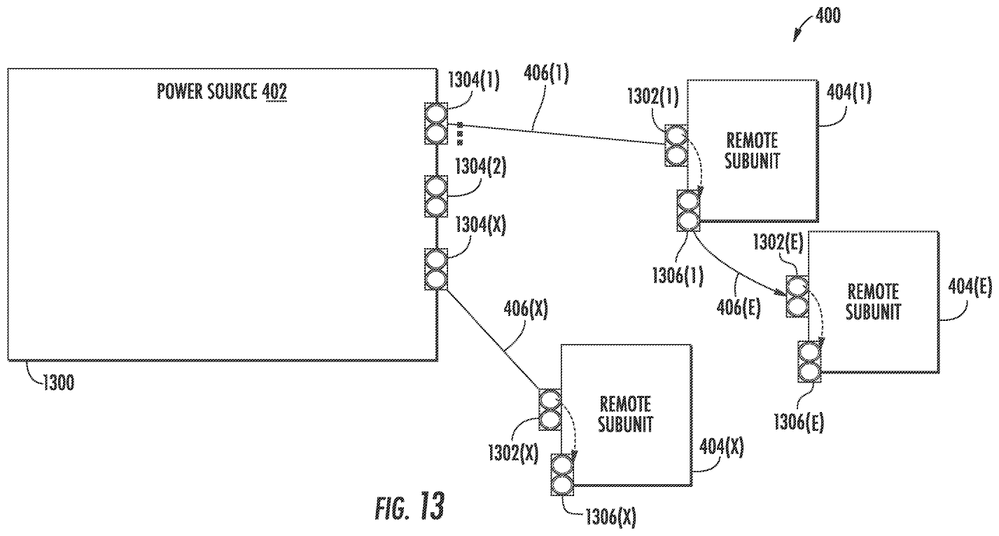

An overview of the current levels and signals of the switch testing is provided in timing diagram 1200 of FIG. 12A. In particular, the activity of the receiver switch 614 of FIG. 6 is provided on the first row 1002. As in FIG. 10A, when the receiver switch 614 is “on,” current flows across the power conductors 610P, 610N and power is supplied to the receiver 604. As noted, the receiver 604 periodically opens the receiver switch 614 (i.e., turns it “off”) as indicated at 1002A, 1002B, etc. As described in reference to FIG. 11A, row 1102 shows the leakage thresholds for the device under test (threshold 1102A, Vt) and the device not under test (threshold 1102B, Vt+Tv).

As further explained in reference to FIG. 11A, row 1104 represents the leakage injection enable signal 944A and its assertion and use. Assuming no actual leakage, the side not under test (e.g., 902B) generates the expected no leakage pulses 1106A, 1106B, 1106C as shown by the third row 1106. The signal of row 1202 corresponds to the signal MOSFET_ON_OFF from management circuit 700 in FIGS. 9A, 9B and turns the switch 704N off at times 1202A and 1202B. The switch 702N is thus open when a no leakage pulses 1204A and 1204B for the side under test are generated as shown in line 1204. Because the switch 702N is open when the pulses 1204A and 1204B are generated, no leakage alarm is generated at times 1206A or 1206B in line 1206.

A process 1250 is provided in FIG. 12B as a flowchart for the testing of the switches 702N, 704N. The process 1250 begins with an interrupt window (block 1252) (e.g., 1002A). The management circuit 700 opens a switch 702N (block 1254). The amplifier 934A receives a first voltage (block 1256) such as at the upstream side 915A of the shunt resistor 712N. The amplifier 934A receives a second voltage (block 1258) such as at the downstream side 915D of the shunt resistor 710N. The amplifier 934A amplifies the differential signal and provides an output to the comparator 936A. The comparator 936A compares the output of the amplifier 934A to a reference value (block 1260) from circuit 944B. When the output of the amplifier 934A exceeds the reference value from the circuit 944B (block 1262), the comparator 936A provides an output to the timed latch 938A (block 1264). The management circuit 700 detects the signal 948A of the timed latch 938A (block 1266). The process 1250 continues by testing a second switch 704N (block 1268). Note that the process 1250 may be spread out over a series of interrupt windows. Thus, block 1268 may take place at a subsequent interrupt window than the original interrupt window of block 1252. Note that if the output of the amplifier 934A does not exceed the reference value at block 1262, then the management circuit 700 may determine if there is still an interrupt window (block 1270). If the answer is no, then the management circuit 700 may end the test and indicate a failure (block 1272).

While the above discussion contemplates a single management circuit 700 operating all the testing of the safety elements, it should be appreciated that each safety element may be tested through its own management circuit (not shown). The separate management circuit version may be easier to implement, but may add complexity for software updates (as multiple instances of the software will require updates). However, evaluating such tradeoffs is a well understood part of the normal design process.

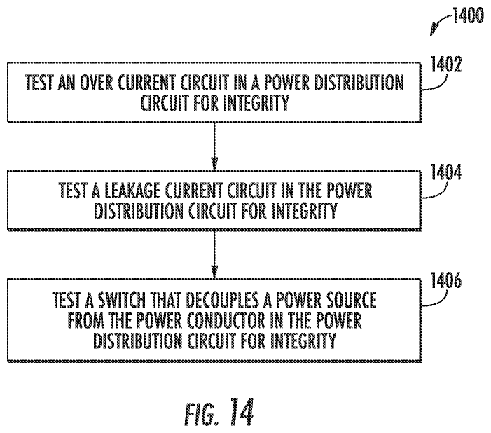

A simplified flowchart of a process 1400 including all three tests is set forth in FIG. 14. The process 1400 includes, during interrupt windows where a remote communication element decouples from a power conductor, testing an over current circuit in a power distribution circuit for integrity (block 1402); testing a leakage current circuit in the power distribution circuit for integrity (block 1404); and testing a switch that decouples a power source from the power conductor in the power distribution circuit for integrity (block 1406).

Note that the present disclosure may be used in a cascaded power distribution network. FIG. 13 is a schematic diagram illustrating the power distribution network 400 of FIG. 4 in the exemplary form of a DCS (or other communications system) with the power source 402 positioned in a power head unit 1300, which is configured to distribute power to a plurality of remote subunits 404(1)-404(X), where at least one remote subunit 404(E) is cascaded relative to another. Each remote subunit 404(1)-404(X) includes a remote power input 1302(1)-1302(X) coupled to the power conductors 406(1)-406(X), respectively, which are configured to be coupled to the power source 402 as previously described in FIG. 4. The power source 402 includes a plurality of power outputs 1304(1)-1304(X) each configured to be coupled to a power conductor 406. The remote subunits 404(1)-404(X) may also have remote power outputs 1306(1)-1306(X) that are configured to carry power from the respective power conductors 406(1)-406(X) received on the remote power inputs 1302(1)-1302(X) to an extended remote subunit, such as extended remote subunit 404(E). Also, as shown in FIG. 13, the extended remote subunit 404(E) may be coupled to the remote subunit 404(1) and also configured to receive power from the power source 402 via the remote subunit 404(1).

Note that any of the referenced inputs herein can be provided as input ports or circuits, and any of the referenced outputs herein can be provided as output ports or circuits.

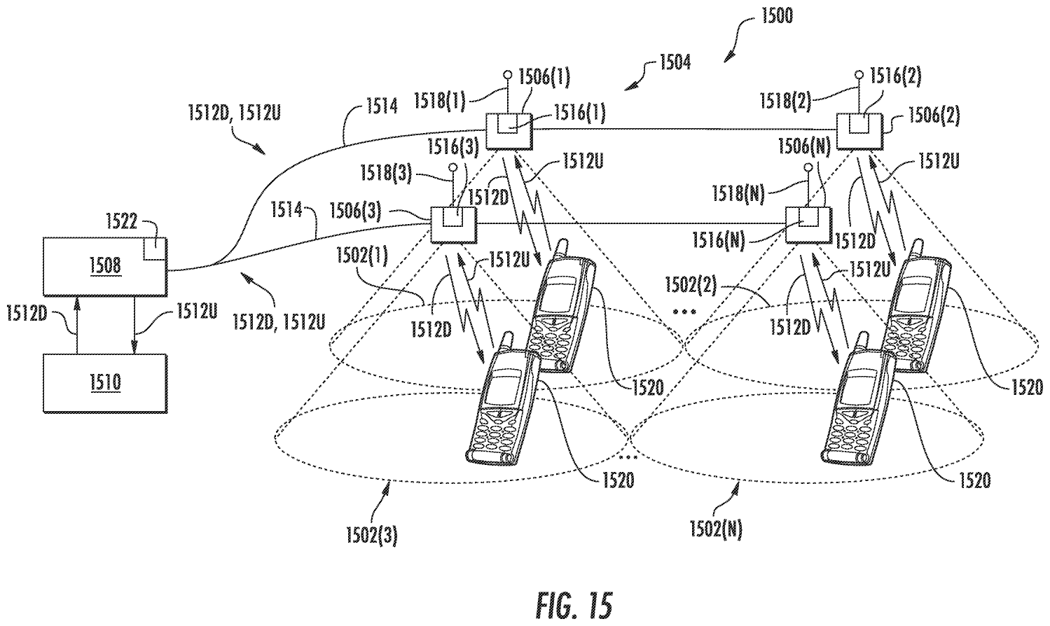

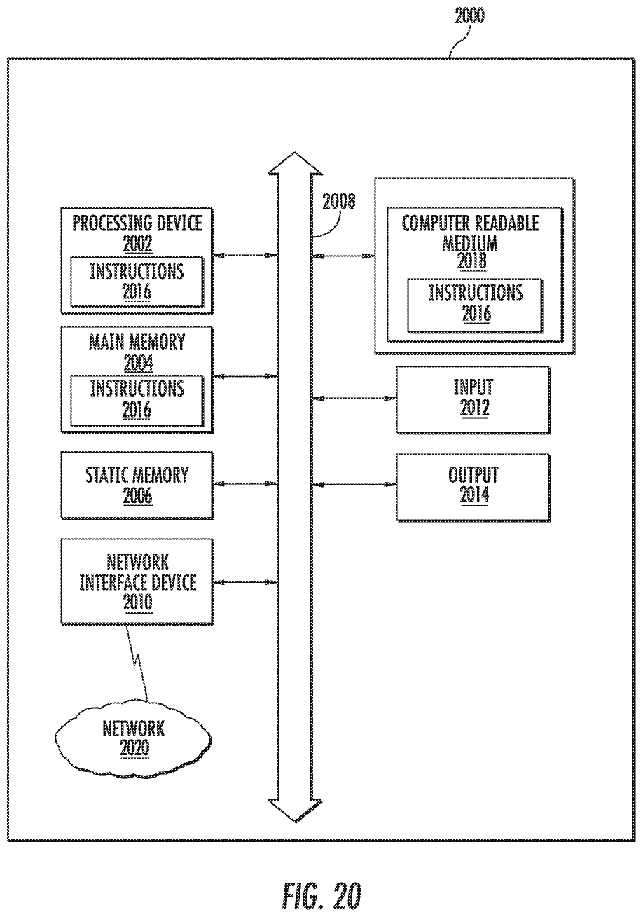

In the interests of completeness, one exemplary DCS having a power distribution network is explored below with reference to FIGS. 15-19 and an exemplary computer that may be used at various locations within a power distribution network is illustrated in FIG. 20. It should be appreciated that the precise context for the power distribution network is not central to the present disclosure.

In this regard, FIG. 15 illustrates a wireless distributed communication system (WDCS) 1500 that is configured to distribute communications services to remote coverage areas 1502(1)-1502(N), where ‘N’ is the number of remote coverage areas. The WDCS 1500 in FIG. 15 is provided in the form of a distributed antenna system (DAS) 1504. The DAS 1504 can be configured to support a variety of communications services that can include cellular communications services, wireless communications services, such as RF identification (RFID) tracking, Wireless Fidelity (Wi-Fi), local area network (LAN), and wireless LAN (WLAN), wireless solutions (Bluetooth, Wi-Fi Global Positioning System (GPS) signal-based, and others) for location-based services, and combinations thereof, as examples. The remote coverage areas 1502(1)-1502(N) are created by and centered on remote units 1506(1)-1506(N) connected to a central unit 1508 (e.g., a head-end controller, a central unit, or a head-end unit). The central unit 1508 may be communicatively coupled to a source transceiver 1510, such as for example, a base transceiver station (BTS) or a baseband unit (BBU). In this regard, the central unit 1508 receives downlink communications signals 1512D from the source transceiver 1510 to be distributed to the remote units 1506(1)-1506(N). The downlink communications signals 1512D can include data communications signals and/or communication signaling signals, as examples. The central unit 1508 is configured with filtering circuits and/or other signal processing circuits that are configured to support a specific number of communications services in a particular frequency bandwidth (i.e., frequency communications bands). The downlink communications signals 1512D are communicated by the central unit 1508 over a communications link 1514 over their frequency to the remote units 1506(1)-1506(N).

With continuing reference to FIG. 15, the remote units 1506(1)-1506(N) are configured to receive the downlink communications signals 1512D from the central unit 1508 over the communications link 1514. The downlink communications signals 1512D are configured to be distributed to the respective remote coverage areas 1502(1)-1502(N) of the remote units 1506(1)-1506(N). The remote units 1506(1)-1506(N) are also configured with filters and other signal processing circuits that are configured to support all or a subset of the specific communications services (i.e., frequency communications bands) supported by the central unit 1508. In a non-limiting example, the communications link 1514 may be a wired communications link, a wireless communications link, or an optical fiber-based communications link. Each of the remote units 1506(1)-1506(N) may include an RF transmitter/receiver 1516(1)-1516(N) and a respective antenna 1518(1)-1518(N) operably connected to the RF transmitter/receiver 1516(1)-1516(N) to wirelessly distribute the communications services to user equipment (UE) 1520 within the respective remote coverage areas 1502(1)-1502(N). The remote units 1506(1)-1506(N) are also configured to receive uplink communications signals 1512U from the UE 1520 in the respective remote coverage areas 1502(1)-1502(N) to be distributed to the source transceiver 1510.

Because the remote units 1506(1)-1506(N) include components that require power to operate, such as the RF transmitter/receivers 1516(1)-1516(N) for example, it is necessary to provide power to the remote units 1506(1)-1506(N). In one example, each remote unit 1506(1)-1506(N) may receive power from a local power source. In another example, the remote units 1506(1)-1506(N) may be powered remotely from a remote power source(s). For example, the central unit 1508 may include a power source 1522 that is configured to remotely supply power over the communications links 1514 to the remote units 1506(1)-1506(N). For example, the communications links 1514 may be cables that include electrical conductors for carrying current (e.g., direct current (DC)) to the remote units 1506(1)-1506(N). If the WDCS 1500 is an optical fiber-based WDCS in which the communications links 1514 include optical fibers, the communications links 1514 may be a “hybrid” cable that includes optical fibers for carrying the downlink and uplink communications signals 1512D, 1512U and separate electrical conductors for carrying current to the remote units 1506(1)-1506(N).

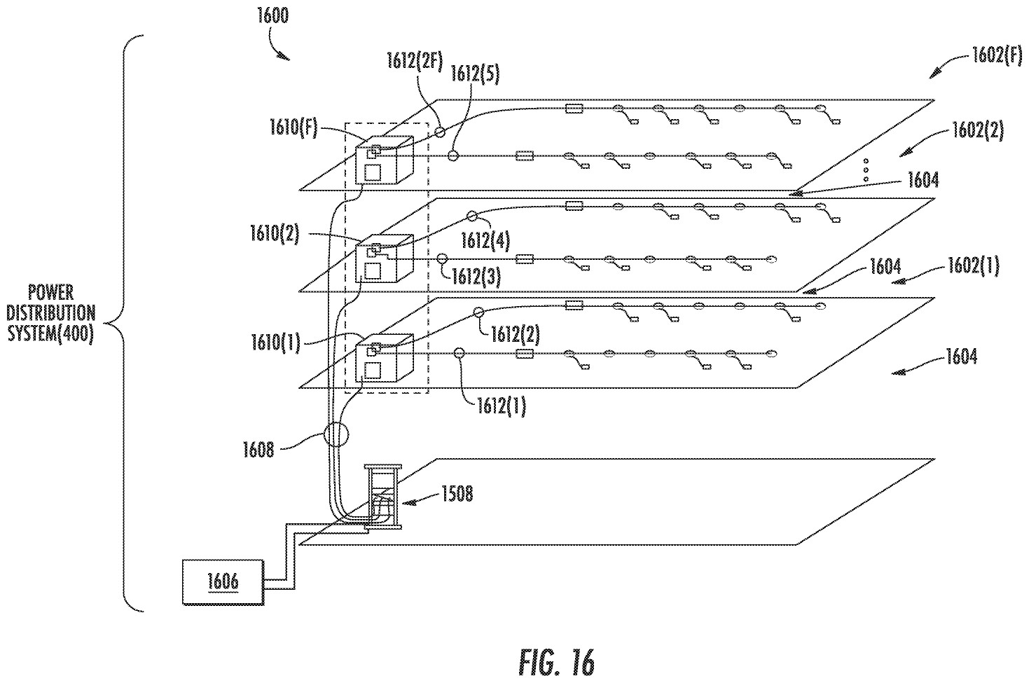

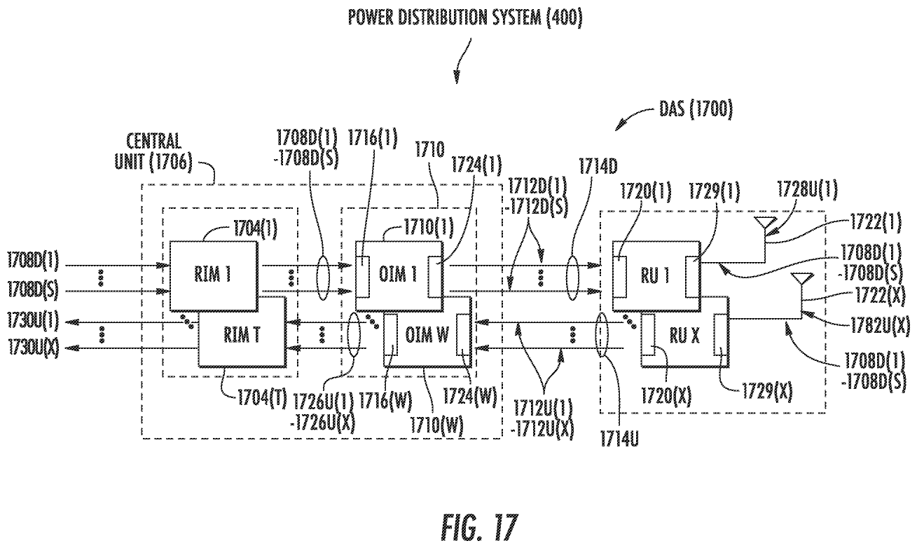

The DAS 1504 and its power distribution network 400 can be provided in an indoor environment as illustrated in FIG. 16. FIG. 16 is a partially schematic cut-away diagram of a building infrastructure 1600 employing the power distribution network 400. The building infrastructure 1600 in this embodiment includes a first (ground) floor 1602(1), a second floor 1602(2), and an Fth floor 1602(F), where ‘F’ can represent any number of floors. The floors 1602(1)-1602(F) are serviced by the central unit 1508 to provide antenna coverage areas 1604 in the building infrastructure 1600. The central unit 1508 is communicatively coupled to a signal source 1606, such as a BTS or BBU, to receive the downlink electrical communications signals. The central unit 1508 is communicatively coupled to the remote subunits to receive uplink optical communications signals from the remote subunits. The downlink and uplink optical communications signals are distributed between the central unit 1508 and the remote subunits over a riser cable 1608 in this example. The riser cable 1608 may be routed through interconnect units (ICUs) 1610(1)-1610(F) dedicated to each floor 1602(1)-1602(F) for routing the downlink and uplink optical communications signals to the remote subunits. The ICUs 1610(1)-1610(F) may also include respective power distribution circuits that include power sources as part of the power distribution network 400, wherein the power distribution circuits are configured to distribute power remotely to the remote subunits to provide power for operating the power-consuming components in the remote subunits. For example, array cables 1612(1)-1612(2F) may be provided and coupled between the ICUs 1610(1)-1610(F) that contain both optical fibers to provide the respective downlink and uplink optical fiber communications media and power conductors (e.g., electrical wire) to carry current from the respective power distribution circuits to the remote subunits.

FIG. 17 is a schematic diagram of an exemplary optical fiber-based DAS 1700 in which a power distribution network can be provided. In this example, the power distribution network 400 is provided in a DCS which is the DAS 1700 in this example. Note that the power distribution network 400 is not limited to being provided in a DCS. A DAS is a system that is configured to distribute communications signals, including wireless communications signals, from a central unit to a plurality of remote subunits over physical communications media, to then be distributed from the remote subunits wirelessly to client devices in wireless communication range of a remote subunit. The DAS 1700 in this example is an optical fiber-based DAS that is comprised of three (3) main components. One or more radio interface circuits provided in the form of radio interface modules (RIMs) 1704(1)-1704(T) are provided in a central unit 1706 to receive and process downlink electrical communications signals 1708D(1)-1708D(S) prior to optical conversion into downlink optical communications signals. The downlink electrical communications signals 1708D(1)-1708D(S) may be received from a base transceiver station (BTS) or baseband unit (BBU) as examples. The downlink electrical communications signals 1708D(1)-1708D(S) may be analog signals or digital signals that can be sampled and processed as digital information. The RIMs 1704(1)-1704(T) provide both downlink and uplink interfaces for signal processing. The notations “1-S” and “1-T” indicate that any number of the referenced component, 1-S and 1-T, respectively, may be provided.

With continuing reference to FIG. 17, the central unit 1706 is configured to accept the plurality of RIMs 1704(1)-1704(T) as modular components that can easily be installed and removed or replaced in a chassis. In one embodiment, the central unit 1706 is configured to support up to twelve (12) RIMs 1704(1)-1704(12). Each RIM 1704(1)-1704(T) can be designed to support a particular type of radio source or range of radio sources (i.e., frequencies) to provide flexibility in configuring the central unit 1706 and the DAS 1700 to support the desired radio sources. For example, one RIM 1704(1)-1704(T) may be configured to support the Personal Communication Services (PCS) radio band. Another RIM 1704(1)-1704(T) may be configured to support the 700 MHz radio band. In this example, by inclusion of these RIMs 1704(1)-1704(T), the central unit 1706 could be configured to support and distribute communications signals, including those for the communications services and communications bands described above as examples.

The RIMs 1704(1)-1704(T) may be provided in the central unit 1706 that support any frequencies desired, including, but not limited to, licensed US FCC and Industry Canada frequencies (824-849 MHz on uplink and 869-894 MHz on downlink), US FCC and Industry Canada frequencies (1850-1915 MHz on uplink and 1930-1995 MHz on downlink), US FCC and Industry Canada frequencies (1710-1755 MHz on uplink and 2110-2155 MHz on downlink), US FCC frequencies (698-716 MHz and 776-787 MHz on uplink and 728-746 MHz on downlink), EU R & TTE frequencies (880-915 MHz on uplink and 925-960 MHz on downlink), EU R & TTE frequencies (1710-1785 MHz on uplink and 1805-1880 MHz on downlink), EU R & TTE frequencies (1920-1980 MHz on uplink and 2110-2170 MHz on downlink), US FCC frequencies (806-824 MHz on uplink and 851-869 MHz on downlink), US FCC frequencies (896-901 MHz on uplink and 929-941 MHz on downlink), US FCC frequencies (793-805 MHz on uplink and 763-775 MHz on downlink), and US FCC frequencies (2495-2690 MHz on uplink and downlink).

With continuing reference to FIG. 17, the received downlink electrical communications signals 1708D(1)-1708D(S) are provided to a plurality of optical interfaces provided in the form of optical interface modules (OIMs) 1710(1)-1710(W) in this embodiment to convert the downlink electrical communications signals 1708D(1)-1708D(S) into downlink optical communications signals 1712D(1)-1712D(S). The notation “1-W” indicates that any number of the referenced component 1-W may be provided. The OIMs 1710(1)-1710(W) may include one or more optical interface components (OICs) that contain electrical-to-optical (E-O) converters 1716(1)-1716(W) to convert the received downlink electrical communications signals 1708D(1)-1708D(S) into the downlink optical communications signals 1712D(1)-1712D(S). The OIMs 1710(1)-1710(W) support the radio bands that can be provided by the RIMs 1704(1)-1704(T), including the examples previously described above. The downlink optical communications signals 1712D(1)-1712D(S) are communicated over a downlink optical fiber communications link 1714D to a plurality of remote subunits (e.g., remote subunits 404) provided in the form of remote subunits in this example. The notation “1-X” indicates that any number of the referenced component 1-X may be provided. One or more of the downlink optical communications signals 1712D(1)-1712D(S) can be distributed to each remote subunit. Thus, the distribution of the downlink optical communications signals 1712D(1)-1712D(S) from the central unit 1706 to the remote subunits is in a point-to-multipoint configuration in this example.

With continuing reference to FIG. 17, the remote subunits include optical-to-electrical (O-E) converters 1720(1)-1720(X) configured to convert the one or more received downlink optical communications signals 1712D(1)-1712D(S) back into the downlink electrical communications signals 1708D(1)-1708D(S) to be wirelessly radiated through antennas 1722(1)-1722(X) in the remote subunits to user equipment (not shown) in the reception range of the antennas 1722(1)-1722(X). The OIMs 1710(1)-1710(W) may also include O-E converters 1724(1)-1724(W) to convert received uplink optical communications signals 1712U(1)-1712U(X) from the remote subunits into uplink electrical communications signals 1726U(1)-1726U(X) as will be described in more detail below.

With continuing reference to FIG. 17, the remote subunits are also configured to receive uplink electrical communications signals 1728U(1)-1728U(X) received by the respective antennas 1722(1)-1722(X) from client devices in wireless communication range of the remote subunits. The uplink electrical communications signals 1728U(1)-1728U(X) may be analog signals or digital signals that can be sampled and processed as digital information. The remote subunits include E-O converters 1729(1)-1729(X) to convert the received uplink electrical communications signals 1728U(1)-1728U(X) into uplink optical communications signals 1712U(1)-1712U(X). The remote subunits distribute the uplink optical communications signals 1712U(1)-1712U(X) over an uplink optical fiber communications link 1714U to the OIMs 1710(1)-1710(W) in the central unit 1706. The O-E converters 1724(1)-1724(W) convert the received uplink optical communications signals 1712U(1)-1712U(X) into uplink electrical communications signals 1730U(1)-1730U(X), which are processed by the RIMs 1704(1)-1704(T) and provided as the uplink electrical communications signals 1730U(1)-1730U(X) to a source transceiver such as a BTS or BBU.

Note that the downlink optical fiber communications link 1714D and the uplink optical fiber communications link 1714U coupled between the central unit 1706 and the remote subunits may be a common optical fiber communications link, wherein for example, wave division multiplexing (WDM) may be employed to carry the downlink optical communications signals 1712D(1)-1712D(S) and the uplink optical communications signals 1712U(1)-1712U(X) on the same optical fiber communications link. Alternatively, the downlink optical fiber communications link 1714D and the uplink optical fiber communications link 1714U coupled between the central unit 1706 and the remote subunits may be single, separate optical fiber communications links, wherein for example, wave division multiplexing (WDM) may be employed to carry the downlink optical communications signals 1712D(1)-1712D(S) on one common downlink optical fiber and the uplink optical communications signals 1712U(1)-1712U(X) on a separate, only uplink optical fiber. Alternatively, the downlink optical fiber communications link 1714D and the uplink optical fiber communications link 1714U coupled between the central unit 1706 and the remote subunits may be separate optical fibers dedicated to and providing a separate communications link between the central unit 1706 and each remote subunit.

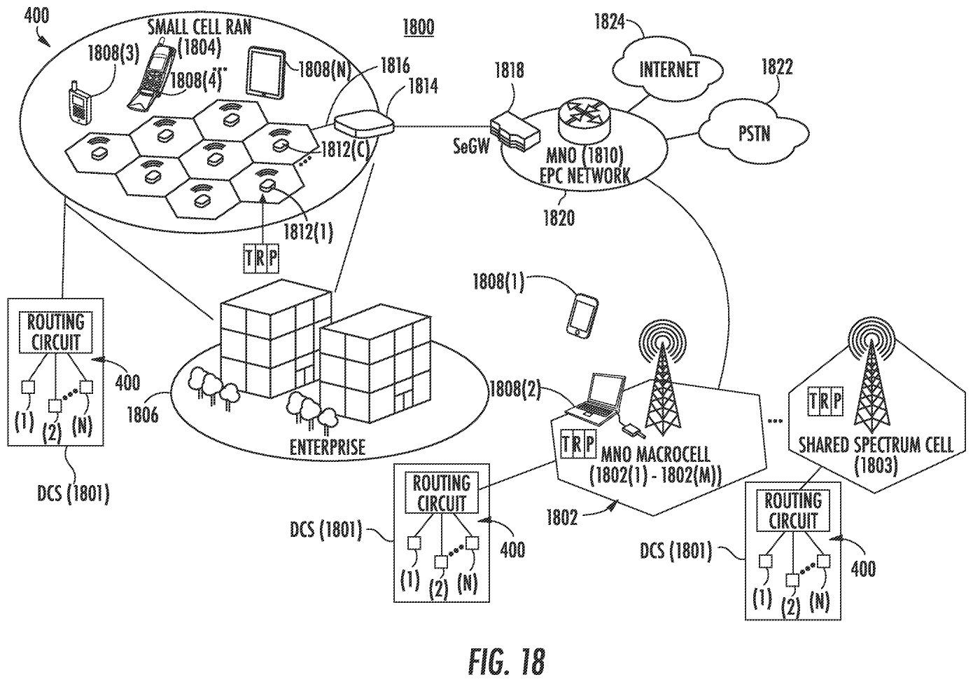

FIG. 18 is a schematic diagram of an exemplary mobile telecommunications environment 1800 that includes an exemplary radio access network (RAN) that includes a mobile network operator (MNO) macrocell employing a radio node, a shared spectrum cell employing a radio node, an exemplary small cell RAN employing a multi-operator radio node located within an enterprise environment as DCSs, and that can include one or more power distribution networks, including the power distribution network 400. The environment 1800 includes exemplary macrocell RANs 1802(1)-1802(M) (“macrocells 1802(1)-1802(M)”) and an exemplary small cell RAN 1804 located within an enterprise environment 1806 and configured to service mobile communications between a user mobile communications device 1808(1)-1808(N) to an MNO 1810. A serving RAN for a user mobile communications device 1808(1)-1808(N) is a RAN or cell in the RAN in which the user mobile communications devices 1808(1)-1808(N) have an established communications session with the exchange of mobile communications signals for mobile communications. Thus, a serving RAN may also be referred to herein as a serving cell. For example, the user mobile communications devices 1808(3)-1808(N) in FIG. 18 are being serviced by the small cell RAN 1804, whereas user mobile communications devices 1808(1) and 1808(2) are being serviced by the macrocell 1802. The macrocell 1802 is an MNO macrocell in this example. However, a shared spectrum RAN 1803 (also referred to as “shared spectrum cell 1803”) includes a macrocell in this example and supports communications on frequencies that are not solely licensed to a particular MNO and thus may service user mobile communications devices 1808(1)-1808(N) independent of a particular MNO. For example, the shared spectrum cell 1803 may be operated by a third party that is not an MNO and wherein the shared spectrum cell 1803 supports Citizen Broadband Radio Service (CBRS). Also, as shown in FIG. 18, the MNO macrocell 1802, the shared spectrum cell 1803, and/or the small cell RAN 1804 can interface with a shared spectrum DCS 1801 supporting coordination of distribution of shared spectrum from multiple service providers to remote subunits to be distributed to subscriber devices. The MNO macrocell 1802, the shared spectrum cell 1803, and the small cell RAN 1804 may be neighboring radio access systems to each other, meaning that some or all can be in proximity to each other such that a user mobile communications device 1808(1)-1808(N) may be able to be in communications range of two or more of the MNO macrocell 1802, the shared spectrum cell 1803, and the small cell RAN 1804 depending on the location of user mobile communications devices 1808(1)-1808(N).

In FIG. 18, the mobile telecommunications environment 1800 in this example is arranged as an LTE (Long Term Evolution) system as described by the Third Generation Partnership Project (3GPP) as an evolution of the GSM/UMTS standards (Global System for Mobile communication/Universal Mobile Telecommunications System). It is emphasized, however, that the aspects described herein may also be applicable to other network types and protocols. The mobile telecommunications environment 1800 includes the enterprise environment 1806 in which the small cell RAN 1804 is implemented. The small cell RAN 1804 includes a plurality of small cell radio nodes 1812(1)-1812(C). Each small cell radio node 1812(1)-1812(C) has a radio coverage area (graphically depicted in the drawings as a hexagonal shape) that is commonly termed a “small cell.” A small cell may also be referred to as a femtocell or, using terminology defined by 3GPP, as a Home Evolved Node B (HeNB). In the description that follows, the term “cell” typically means the combination of a radio node and its radio coverage area unless otherwise indicated.

In FIG. 18, the small cell RAN 1804 includes one or more services nodes (represented as a single services node 1814) that manage and control the small cell radio nodes 1812(1)-1812(C). In alternative implementations, the management and control functionality may be incorporated into a radio node, distributed among nodes, or implemented remotely (i.e., using infrastructure external to the small cell RAN 1804). The small cell radio nodes 1812(1)-1812(C) are coupled to the services node 1814 over a direct or local area network (LAN) connection 1816 as an example, typically using secure IPsec tunnels. The small cell radio nodes 1812(1)-1812(C) can include multi-operator radio nodes. The services node 1814 aggregates voice and data traffic from the small cell radio nodes 1812(1)-1812(C) and provides connectivity over an IPsec tunnel to a security gateway (SeGW) 1818 in a network 1820 (e.g., evolved packet core (EPC) network in a 4G network, or 5G Core in a 5G network) of the MNO 1810. The network 1820 is typically configured to communicate with a public switched telephone network (PSTN) 1822 to carry circuit-switched traffic, as well as for communicating with an external packet-switched network such as the Internet 1824.

The environment 1800 also generally includes a node (e.g., eNodeB or gNodeB) base station, or “macrocell” 1802. The radio coverage area of the macrocell 1802 is typically much larger than that of a small cell where the extent of coverage often depends on the base station configuration and surrounding geography. Thus, a given user mobile communications device 1808(1)-1808(N) may achieve connectivity to the network 1820 (e.g., EPC network in a 4G network, or 5G Core in a 5G network) through either a macrocell 1802 or small cell radio node 1812(1)-1812(C) in the small cell RAN 1804 in the environment 1800.

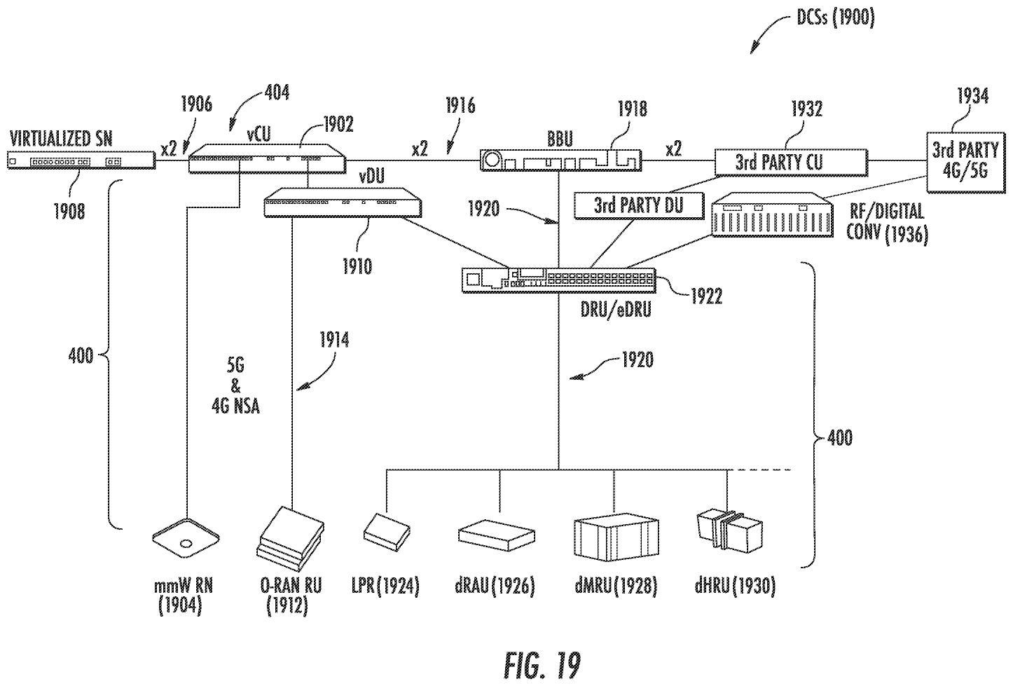

FIG. 19 is a schematic diagram illustrating exemplary DCSs 1900 that support 4G and 5G communications services. The DCSs 1900 in FIG. 19 can include one or more power distribution networks, including the power distribution network 400 in FIG. 4, configured to perform a line capacitance discharge of power conductors between a power source and a remote unit(s) when a safety disconnect of the power source is performed in response to a measured current from the connected power source when the remote unit is decoupled from the power source. The DCSs 1900 support both legacy 4G LTE, 4G/5G non-standalone (NSA), and 5G communications systems. As shown in FIG. 19, a centralized services node 1902 is provided that is configured to interface with a core network to exchange communications data and distribute the communications data as radio signals to remote subunits. In this example, the centralized services node 1902 is configured to support distributed communications services to a millimeter wave (mmW) radio node 1904. The functions of the centralized services node 1902 can be virtualized through an x2 interface 1906 to another services node 1908. The centralized services node 1902 can also include one or more internal radio nodes that are configured to be interfaced with a distribution node 1910 to distribute communications signals for the radio nodes to an open RAN (O-RAN) remote unit 1912 that is configured to be communicatively coupled through an O-RAN interface 1914.

The centralized services node 1902 can also be interfaced through an x2 interface 1916 to a BBU 1918 that can provide a digital signal source to the centralized services node 1902. The BBU 1918 is configured to provide a signal source to the centralized services node 1902 to provide radio source signals 1920 to the O-RAN remote unit 1912 as well as to a distributed router unit (DRU) 1922 as part of a digital DAS. The DRU 1922 is configured to split and distribute the radio source signals 1920 to different types of remote subunits, including a lower-power remote unit (LPR) 1924, a radio antenna unit (dRAU) 1926, a mid-power remote unit (dMRU) 1928, and a high-power remote unit (dHRU) 1930. The BBU 1918 is also configured to interface with a third party central unit 1932 and/or an analog source 1934 through an radio frequency (RF)/digital converter 1936.

FIG. 20 is a schematic diagram representation of additional detail illustrating a computer system 2000 that could be employed in any component or circuit in a power distribution network, including the power distribution network 400 in FIG. 4, configured to perform a line capacitance discharge of power conductors between a power source and a remote unit(s) when a safety disconnect of the power source is performed in response to a measured current from the connected power source when the remote unit is decoupled from the power source. In this regard, the computer system 2000 is adapted to execute instructions from an exemplary computer-readable medium to perform these and/or any of the functions or processing described herein. The computer system 2000 in FIG. 20 may include a set of instructions that may be executed to program and configure programmable digital signal processing circuits in a DCS for supporting scaling of supported communications services. The computer system 2000 may be connected (e.g., networked) to other machines in a LAN, an intranet, an extranet, or the Internet. While only a single device is illustrated, the term “device” shall also be taken to include any collection of devices that individually or jointly execute a set (or multiple sets) of instructions to perform any one or more of the methodologies discussed herein. The computer system 2000 may be a circuit or circuits included in an electronic board card, such as, a printed circuit board (PCB), a server, a personal computer, a desktop computer, a laptop computer, a personal digital assistant (PDA), a computing pad, a mobile device, or any other device, and may represent, for example, a server or a user's computer.

The exemplary computer system 2000 in this embodiment includes a processing device or processor 2002, a main memory 2004 (e.g., read-only memory (ROM), flash memory, dynamic random access memory (DRAM), such as synchronous DRAM (SDRAM), etc.), and a static memory 2006 (e.g., flash memory, static random access memory (SRAM), etc.), which may communicate with each other via a data bus 2008. Alternatively, the processor 2002 may be connected to the main memory 2004 and/or static memory 2006 directly or via some other connectivity means. The processor 2002 may be a controller, and the main memory 2004 or static memory 2006 may be any type of memory.

The processor 2002 represents one or more general-purpose processing devices, such as a microprocessor, central processing unit, or the like. More particularly, the processor 2002 may be a complex instruction set computing (CISC) microprocessor, a reduced instruction set computing (RISC) microprocessor, a very long instruction word (VLIW) microprocessor, a processor implementing other instruction sets, or other processors implementing a combination of instruction sets. The processor 2002 is configured to execute processing logic in instructions for performing the operations and steps discussed herein.

The computer system 2000 may further include a network interface device 2010. The computer system 2000 also may or may not include an input 2012, configured to receive input and selections to be communicated to the computer system 2000 when executing instructions. The computer system 2000 also may or may not include an output 2014, including, but not limited to, a display, a video display unit (e.g., a liquid crystal display (LCD) or a cathode ray tube (CRT)), an alphanumeric input device (e.g., a keyboard), and/or a cursor control device (e.g., a mouse).

The computer system 2000 may or may not include a data storage device that includes instructions 2016 stored in a computer-readable medium 2018. The instructions 2016 may also reside, completely or at least partially, within the main memory 2004 and/or within the processor 2002 during execution thereof by the computer system 2000, the main memory 2004 and the processor 2002 also constituting computer-readable medium. The instructions 2016 may further be transmitted or received over a network 2020 via the network interface device 2010.

While the computer-readable medium 2018 is shown in an exemplary embodiment to be a single medium, the term “computer-readable medium” should be taken to include a single medium or multiple media (e.g., a centralized or distributed database, and/or associated caches and servers) that store the one or more sets of instructions. The term “computer-readable medium” shall also be taken to include any medium that is capable of storing, encoding, or carrying a set of instructions for execution by the processing device and that cause the processing device to perform any one or more of the methodologies of the embodiments disclosed herein. The term “computer-readable medium” shall accordingly be taken to include, but not be limited to, solid-state memories, optical medium, and magnetic medium.

While exemplary aspects of the present disclosure have been discussed in the context of the remote subunit 404 disconnecting from the power source 402, the present disclosure is not so limited. In particular, the present disclosure may be used with systems that disconnect from the power source with appropriate changes to the data modulation. That is, data is transferred from the power source to the remote subunits by changing the PRI and data from the remote subunit to the power source is modulated by extending an interrupt time period (i.e., a switch at the remote subunit will keep the circuit open for longer). Data received at the power source will be detected by measuring the time extension of the default interrupt time period and data received at the remote subunit will be detected by measuring the time interval between PM rising edges using current measurements.

The embodiments disclosed herein include various steps. The steps of the embodiments disclosed herein may be formed by hardware components or may be embodied in machine-executable instructions, which may be used to cause a general-purpose or special-purpose processor programmed with the instructions to perform the steps. Alternatively, the steps may be performed by a combination of hardware and software.

The embodiments disclosed herein may be provided as a computer program product, or software, that may include a machine-readable medium (or computer-readable medium) having stored thereon instructions, which may be used to program a computer system (or other electronic devices) to perform a process according to the embodiments disclosed herein. A machine-readable medium includes any mechanism for storing or transmitting information in a form readable by a machine (e.g., a computer). For example, a machine-readable medium includes: a machine-readable storage medium (e.g., ROM, random access memory (“RAM”), a magnetic disk storage medium, an optical storage medium, flash memory devices, etc.); and the like.

Unless specifically stated otherwise and as apparent from the previous discussion, it is appreciated that throughout the description, discussions utilizing terms such as “processing,” “computing,” “determining,” “displaying,” or the like, refer to the action and processes of a computer system, or similar electronic computing device, that manipulates and transforms data and memories represented as physical (electronic) quantities within the computer system's registers into other data similarly represented as physical quantities within the computer system memories or registers or other such information storage, transmission, or display devices.

The algorithms and displays presented herein are not inherently related to any particular computer or other apparatus. Various systems may be used with programs in accordance with the teachings herein, or it may prove convenient to construct more specialized apparatuses to perform the required method steps. The required structure for a variety of these systems will appear from the description above. In addition, the embodiments described herein are not described with reference to any particular programming language. It will be appreciated that a variety of programming languages may be used to implement the teachings of the embodiments as described herein.

Those of skill in the art will further appreciate that the various illustrative logical blocks, modules, circuits, and algorithms described in connection with the embodiments disclosed herein may be implemented as electronic hardware, instructions stored in memory or in another computer-readable medium and executed by a processor or other processing device, or combinations of both. The components of the distributed antenna systems described herein may be employed in any circuit, hardware component, integrated circuit (IC), or IC chip, as examples. Memory disclosed herein may be any type and size of memory and may be configured to store any type of information desired. To clearly illustrate this interchangeability, various illustrative components, blocks, modules, circuits, and steps have been described above generally in terms of their functionality. How such functionality is implemented depends on the particular application, design choices, and/or design constraints imposed on the overall system. Skilled artisans may implement the described functionality in varying ways for each particular application, but such implementation decisions should not be interpreted as causing a departure from the scope of the present embodiments.

The various illustrative logical blocks, modules, and circuits described in connection with the embodiments disclosed herein may be implemented or performed with a processor, a Digital Signal Processor (DSP), an Application Specific Integrated Circuit (ASIC), a Field Programmable Gate Array (FPGA), or other programmable logic device, a discrete gate or transistor logic, discrete hardware components, or any combination thereof designed to perform the functions described herein. Furthermore, a controller may be a processor. A processor may be a microprocessor, but in the alternative, the processor may be any conventional processor, controller, microcontroller, or state machine. A processor may also be implemented as a combination of computing devices (e.g., a combination of a DSP and a microprocessor, a plurality of microprocessors, one or more microprocessors in conjunction with a DSP core, or any other such configuration).

The embodiments disclosed herein may be embodied in hardware and in instructions that are stored in hardware, and may reside, for example, in RAM, flash memory, ROM, Electrically Programmable ROM (EPROM), Electrically Erasable Programmable ROM (EEPROM), registers, a hard disk, a removable disk, a CD-ROM, or any other form of computer-readable medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a remote station. In the alternative, the processor and the storage medium may reside as discrete components in a remote station, base station, or server.

It is also noted that the operational steps described in any of the exemplary embodiments herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary embodiments may be combined. Those of skill in the art will also understand that information and signals may be represented using any of a variety of technologies and techniques. For example, data, instructions, commands, information, signals, bits, symbols, and chips, that may be references throughout the above description, may be represented by voltages, currents, electromagnetic waves, magnetic fields, or particles, optical fields or particles, or any combination thereof.

Unless otherwise expressly stated, it is in no way intended that any method set forth herein be construed as requiring that its steps be performed in a specific order. Accordingly, where a method claim does not actually recite an order to be followed by its steps, or it is not otherwise specifically stated in the claims or descriptions that the steps are to be limited to a specific order, it is in no way intended that any particular order be inferred.

It will be apparent to those skilled in the art that various modifications and variations can be made without departing from the spirit or scope of the invention. Since modifications, combinations, sub-combinations and variations of the disclosed embodiments incorporating the spirit and substance of the invention may occur to persons skilled in the art, the invention should be construed to include everything within the scope of the appended claims and their equivalents.

What is claimed is:

1. A method of testing integrity for safety elements in a power distribution network configured to deliver power to remote elements, the method comprising:
during interrupt windows where a remote element decouples from a power conductor:
testing an over current circuit in a power distribution circuit for integrity;
testing a leakage current circuit in the power distribution circuit for integrity; and
testing a switch that decouples a power source from the power conductor in the power distribution circuit for integrity.

2. The method of claim 1, wherein testing the leakage current circuit comprises testing at a different interrupt window than testing the over current circuit.

3. The method of claim 1, wherein testing the over current circuit comprises testing a first over current circuit and a second over current circuit for integrity.

4. The method of claim 1, wherein testing the leakage current circuit comprises testing a first leakage current circuit and a second leakage current circuit.

5. The method of claim 1, wherein testing the switch comprises testing a first switch and a second switch.

6. The method of claim 1, wherein during interrupt windows where the remote element decouples from a positive power conductor, testing the switch comprises testing a switch that decouples the power source from the positive power conductor.

7. The method of claim 1, wherein during interrupt windows where the remote element decouples from a negative power conductor, testing the switch comprises testing a switch that decouples the power source from the negative power conductor.

8. The method of claim 1, wherein the method occurs during interrupt windows where the remote element decouples from both a positive power conductor and a negative power conductor.

9. The method of claim 8, wherein testing the over current circuit comprises testing a first over current circuit and a second over current circuit associated with the positive power conductor for integrity and testing a third over current circuit and a fourth over current circuit associated with the negative power conductor for integrity.

10. The method of claim 8, wherein testing the leakage current circuit comprises testing a first leakage current circuit and a second leakage current circuit associated with the positive power conductor for integrity and testing a third leakage current circuit and a fourth leakage current circuit associated with the negative power conductor for integrity.

11. The method of claim 8, wherein testing the switch comprises testing a first switch and a second switch associated with the positive power conductor for integrity and testing a third switch and a fourth switch associated with the negative power conductor for integrity.

12. The method of claim 1, further comprising providing power to the remote element.

13. The method of claim 12, wherein providing power to the remote element comprises providing power to a remote communication element in a wireless communication system.

14. A method for testing integrity for an over current circuit in a power distribution network configured to deliver power to remote elements, the method comprising:
during interrupt windows where a remote element decouples from a power conductor:
receiving a first voltage at an amplifier;
receiving a second voltage at the amplifier;
comparing an output of the amplifier to a reference value with a comparator;
when the output of the amplifier exceeds the reference value, providing an output to a latch circuit; and
detecting an output of the latch circuit with a management circuit.

15. The method of claim 14, wherein receiving the first voltage comprises receiving an upstream voltage measured upstream of a first shunt resistor and wherein receiving the second voltage comprises receiving a downstream voltage measured downstream of a second shunt resistor.

16. The method of claim 14, further comprising repeating the method on a second over current circuit.

17. The method of claim 14, further comprising providing a test current from a voltage source.

18. The method of claim 14, further comprising providing power to the remote element.

19. The method of claim 18, wherein providing power to the remote element comprises providing power to a remote communication element in a wireless communication system.

20-41. (canceled)
